(19) United States
(12) Patent Application Publication
(10) Pub. No.: US 2025/0294747 A1
(43) Pub. Date: Sep. 18, 2025

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Jeongeun Lee, Suwon-si (KR); Chang-Bum Kim, Suwon-si (KR); Sunghoon Kim, Suwon-si (KR); Jung-Seok Hwang, Suwon-si (KR)

(21) Appl. No.: 18/903,599

(22) Filed: Oct. 1, 2024

(30) Foreign Application Priority Data
Mar. 14, 2024 (KR) 10-2024-0035868

(51) Int. Cl. H10B 43/27; H10B 43/35; H10B 43/40

(52) U.S. Cl. CPC H10B 43/27; H10B 43/35; H10B 43/40

(57) ABSTRACT

A semiconductor device includes a substrate, a circuit element and a wiring portion disposed on the substrate, a gate stacked structure including a plurality of interlayer insulation layers and a plurality of gate electrodes alternately stacked on the wiring portion, a channel structure penetrating the gate stacked structure, an upper insulation layer covering an upper surface of the wiring portion and the gate stacked structure, a connection contact structure connected to the circuit element by penetrating the upper insulation layer at an outer side of the gate stacked structure, and a dummy contact structure disposed adjacent to the connection contact structure, and having a lower dielectric constant than the connection contact structure.

### CROSS-REFERENCE TO RELATED APPLICATION

This application claims priority to Korean Patent Application No. 10-2024-0035868, filed in the Korean Intellectual Property Office on Mar. 14, 2024, the entire content of which is incorporated herein by reference.

### BACKGROUND

In electronic systems that require data storage, semiconductor devices capable of storing high-capacity data are required. Accordingly, ways to increase the data storage capacity of semiconductor devices are being studied. For example, a semiconductor device including memory cells arranged three-dimensionally instead of memory cells arranged two-dimensionally has been proposed.

### SUMMARY

The present disclosure provides a semiconductor device and an electronic system including the same having an advantage in high-speed operation by decreasing the parasitic capacitance.

A semiconductor device may include a substrate, a circuit element and a wiring portion disposed on the substrate, a gate stacked structure including a plurality of interlayer insulation layers and a plurality of gate electrodes alternately stacked on the wiring portion, a channel structure penetrating the gate stacked structure, an upper insulation layer covering an upper surface of the wiring portion and the gate stacked structure, a connection contact structure connected to the circuit element by penetrating the upper insulation layer at an outer side of the gate stacked structure, and a dummy contact structure disposed adjacent to the connection contact structure, and having a lower dielectric constant than the connection contact structure.

A semiconductor device may include a substrate, a circuit element and a wiring portion disposed on the substrate, a gate stacked structure including a plurality of interlayer insulation layers and a plurality of gate electrodes alternately stacked on the wiring portion, a channel structure penetrating the gate stacked structure, an upper insulation layer covering an upper surface of the wiring portion and the gate stacked structure, a connection contact structure connected to the circuit element by penetrating the upper insulation layer at an outer side of the gate stacked structure, and a dummy contact structure disposed adjacent to the connection contact structure, and including a different material from the connection contact structure.

An electronic system may include a main substrate, a semiconductor device on the main substrate, and a controller electrically connected to the semiconductor device on the main substrate, where, the semiconductor device may include the substrate, a circuit element and a wiring portion disposed on the substrate, a gate stacked structure including a plurality of interlayer insulation layers and a plurality of gate electrodes alternately stacked on the wiring portion, a channel structure penetrating the gate stacked structure, an upper insulation layer covering an upper surface of the wiring portion and the gate stacked structure, a connection contact structure connected to the circuit element by penetrating the upper insulation layer at an outer side of the gate stacked structure, and a dummy contact structure disposed adjacent to the connection contact structure, and having a lower dielectric constant than the connection contact structure.

According to some implementations, the performance of high-speed operation of a semiconductor device and an electronic system including the same may be improved by decreasing the parasitic capacitance.

### BRIEF DESCRIPTION OF THE DRAWINGS

FIG. 1 is a cross-sectional view schematically showing a semiconductor device according to some implementations.

FIG. 2 and FIG. 3 are enlarged cross-sectional views showing various examples of a channel structure included in the semiconductor device of FIG. 1.

FIG. 4 is an enlarged cross-sectional view showing Pl of the semiconductor device of FIG. 1.

FIG. 5 to FIG. 7 are drawings showing various examples of a dummy contact structure of a semiconductor device according to some implementations.

FIG. 8 to FIG. 12 are drawings showing various examples of an arrangement in a plan view of a connection contact structure and a dummy contact structure of a semiconductor device according to some implementations.

FIG. 13 and FIG. 14 are plan views showing various examples of a circuit element connected to a connection contact structure of a semiconductor device according to some implementations.

FIG. 15 and FIG. 17 are perspective views showing various wire structures of a connection wire layer connected by a connection contact structure of a semiconductor device according to some implementations.

FIG. 16 and FIG. 18 are plan views showing various wire structures of a connection wire layer connected by a connection contact structure of a semiconductor device according to some implementations.

FIG. 19 is a cross-sectional view showing a semiconductor device according to some implementations.

FIG. 20 is a drawing schematically showing an electronic system including a semiconductor device according to some implementations.

FIG. 21 is a perspective view schematically showing an electronic system including a semiconductor device according to some implementations.

FIG. 22 and FIG. 23 are cross-sectional views each schematically showing a semiconductor package according to some implementations.

### DETAILED DESCRIPTION

The present disclosure will be described more fully hereinafter with reference to the accompanying drawings, in which implementations of the disclosure are shown. As those skilled in the art would realize, the described implementations may be modified in various different ways, all without departing from the spirit or scope of the present disclosure.

In order to clearly describe the present invention, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

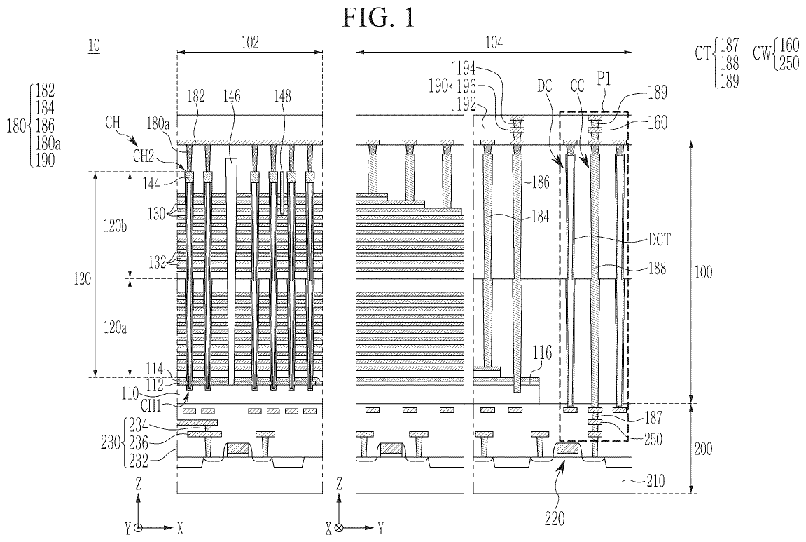

Hereinafter, referring to FIG. 1 to FIG. 4, a semiconductor device according to some implementations will be described.

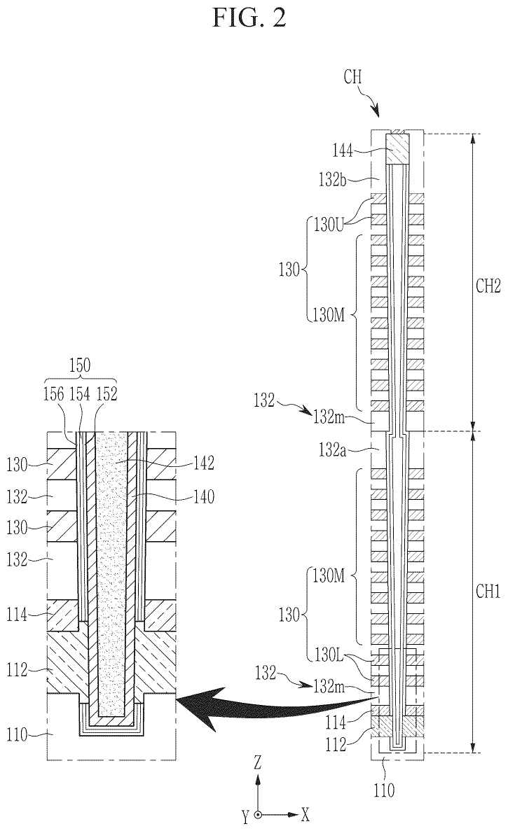

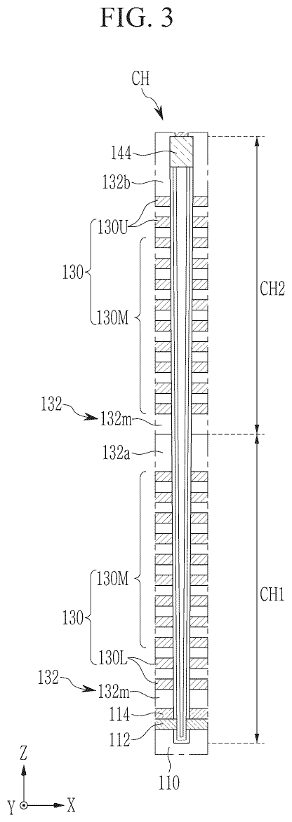

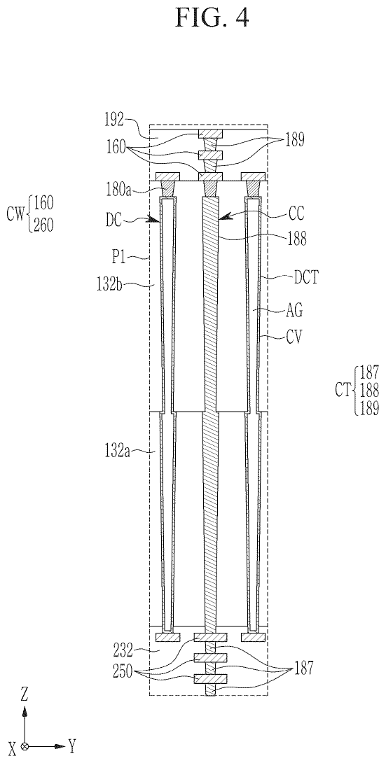

FIG. 1 is a cross-sectional view schematically showing a semiconductor device according to some implementations. FIG. 2 and FIG. 3 are enlarged cross-sectional views showing various examples of a channel structure included in the semiconductor device of FIG. 1. FIG. 4 is an enlarged cross-sectional view showing Pl of the semiconductor device of FIG. 1.

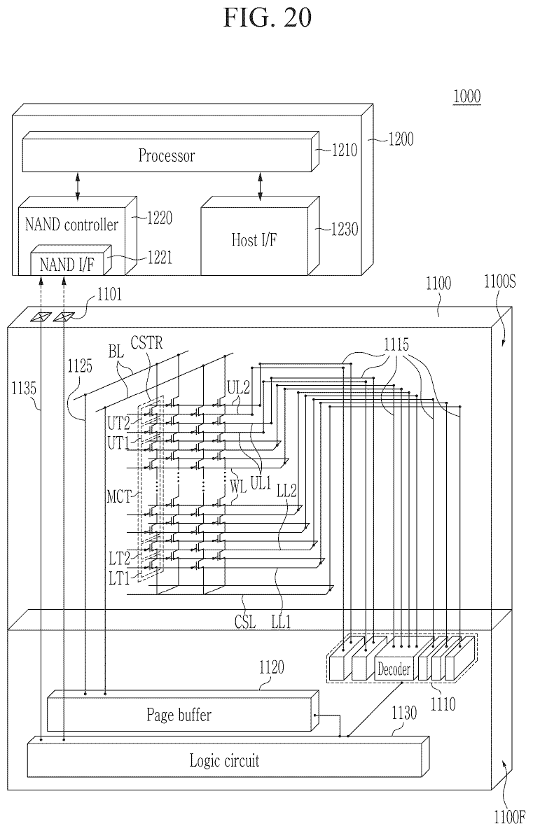

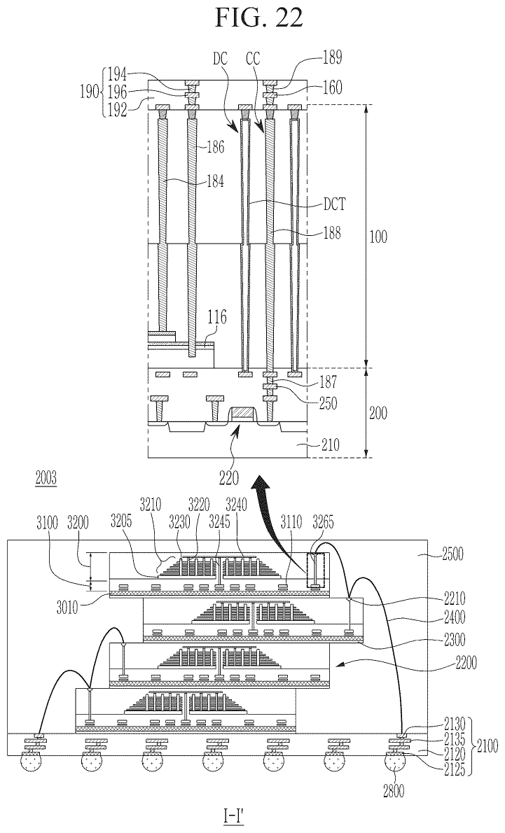

Referring to FIG. 1 to FIG. 4, a semiconductor device 10 according to some implementations includes a cell region 100 provided with a memory cell structure and a circuit region 200 provided with a peripheral circuit structure configured to control an operation of the memory cell structure. For example, the circuit region 200 and the cell region 100 may be portions corresponding to a first structure 1100F and a second structure 1100S of a semiconductor device 1100 included in an electronic system 1000 shown in FIG. 20, respectively. Alternatively, the circuit region 200 and the cell region 100 may be portions corresponding to a first structure 3100 and a second structure 3200 of a semiconductor chip 2200 shown in FIG. 22. Here, the circuit region 200 may include a peripheral circuit structure formed on a first substrate 210, and the cell region 100 may include a gate stacked structure 120 and a channel structure CH located on a cell array region 102 of a second substrate 110 as the memory cell structure. A first wiring portion 230 electrically connected to the peripheral circuit structure may be located in the circuit region 200, and a second wiring portion 190 electrically connected to the memory cell structure may be located in the cell region 100.

In some implementations, the cell region 100 may be located on the circuit region 200. According to this, since an area corresponding to the circuit region 200 may not be secured separately from the cell region 100, an area of the semiconductor device 10 may be reduced. However, implementations are not limited thereto, and the circuit region 200 may be located adjacent to the cell region 100. Various other changes are available.

The circuit region 200 includes the first substrate 210, and a circuit element 220 and the first wiring portion 230 located on the first substrate 210.

The first substrate 210 may be a semiconductor substrate including a semiconductor material. For example, the first substrate 210 may be a semiconductor substrate made of a semiconductor material, and may be a semiconductor substrate in which a semiconductor layer is formed on a base substrate. For example, the first substrate 210 may be formed of silicon, epitaxial silicon, germanium, silicon-germanium, silicon-on-insulator (SOI), or germanium-on-insulator (GOI), or the like.

The circuit element 220 formed on the first substrate 210 may include various circuit elements configured to control an operation of a memory cell structure provided in the cell region 100. For example, the circuit element 220 may configure a peripheral circuit structure such as a decoder circuit (see reference symbol 1110 of FIG. 20), a page buffer (see reference symbol 1120 of FIG. 20), a logic circuit (see reference symbol 1130 of FIG. 20), or the like.

The circuit element 220 may include, for example, a transistor, but is not limited thereto. For example, the circuit element 220 may include not only an active element such as a transistor but also a passive element such as a capacitor, a resistor, a inductor, or the like.

The first wiring portion 230 located on the first substrate 210 may be electrically connected to the circuit element 220. In some implementations, the first wiring portion 230 includes a plurality of first wire layers 236 spaced apart from each other interposing a first insulation layer 232 and connected to form a desired path by a first contact 234. The first wire layer 236 or the first contact 234 may include various conductive materials, and the first insulation layer 232 may include various insulating materials.

The cell region 100 includes the cell array region 102 and a connection region 104. In the cell array region 102, the gate stacked structure 120 and the channel structure CH may be located on the second substrate 110. A structure for connecting the gate stacked structure 120 and/or the channel structure CH located in the cell array region 102 to the circuit region 200 or external circuit may be located in the connection region 104.

In some implementations, the second substrate 110 may include a semiconductor material. For example, the second substrate 110 may include polysilicon doped with impurities. The second substrate 110 may perform the function of a common source line. The second substrate 110 may function as a source region configured to supply a current to memory cells located on the second substrate 110. The second substrate 110 may be formed in the shape of a plate. That is, the second substrate 110 may be formed as a plate common source line.

In the cell array region 102, the gate stacked structure 120 including a cell insulation layer 132 and a gate electrode 130 alternately stacked on a first surface (e.g., front surface or upper surface) of the second substrate 110, and the channel structure CH penetrating the gate stacked structure 120 to extend in a direction crossing the second substrate 110 may be located.

Horizontal conductive layers 112 and 114 may be provided between the second substrate 110 and the gate stacked structure 120 in the cell array region 102. The horizontal conductive layers 112 and 114 may serve to electrically connect between the channel structure CH and the second substrate 110. For example, the horizontal conductive layers 112 and 114 may include a first horizontal conductive layer 112 located on the first surface of the second substrate 110, and may further include a second horizontal conductive layer 114 located on the first horizontal conductive layer 112. That is, the first horizontal conductive layer 112 may be located between the second substrate 110 and the second horizontal conductive layer 114. Between the second substrate 110 and the gate stacked structure 120 in a portion region of the connection region 104, the first horizontal conductive layer 112 may not be provided, but a horizontal insulation layer 116 may be provided. During the manufacturing process, a portion of the horizontal insulation layer 116 may be replaced with the first horizontal conductive layer 112, and another portion of the horizontal insulation layer 116 located in the connection region 104 may remain in the connection region 104.

The first horizontal conductive layer 112 may function as a portion of common source line of the semiconductor device 10. For example, the first horizontal conductive layer 112 may function as a common source line together with the second substrate 110. As shown in the enlarged view of FIG. 2, the channel structure CH may penetrate the horizontal conductive layers 112 and 114 to extend to reach the second substrate 110, and a gate dielectric layer 150 may be removed from a portion where the first horizontal conductive layer 112 is located such that the first horizontal conductive layer 112 may be directly connected to the channel layer 140 on a circumference of a channel layer 140. Therefore, the first horizontal conductive layer 112 may electrically connect between the second substrate 110 and the channel layer 140.

First and second horizontal conductive layers 112 and 114 may include a semiconductor material (e.g., polysilicon). For example, the first horizontal conductive layer 112 may include polysilicon doped with impurities, and the second horizontal conductive layer 114 may be a layer that includes polysilicon doped with impurities or includes impurities diffused from the first horizontal conductive layer 112. However, implementations are not limited thereto, and the second horizontal conductive layer 114 may include an insulating material. Alternatively, the second horizontal conductive layer 114 may not be provided separately.

The gate stacked structure 120 in which the cell insulation layer 132 and the gate electrode 130 are alternately stacked may be located on the second substrate 110 (e.g., on the first and second horizontal conductive layers 112 and 114 formed on the second substrate 110).

In some implementations, the gate stacked structure 120 includes a plurality of gate stacked structures 120a and 120b sequentially stacked on the second substrate 110. Then, the number of the stacked gate electrode 130 may be increased, and the number of memory cells may be increased in a stable structure. For example, the gate stacked structure 120 may include first and second gate stacked structures 120a and 120b such that the structure may be simplified while increasing data storage capacity. However, implementations are not limited thereto, and the gate stacked structure 120 may be configured as one gate stacked structure, and may include three or more gate stacked structures.

In the gate stacked structure 120, the gate electrode 130 includes a lower gate electrode 130L, a memory cell gate electrode 130M, an upper gate electrode 130U, which are sequentially located on the second substrate 110. The lower gate electrode 130L may be used as a gate electrode of a ground select transistor, and the memory cell gate electrode 130M may configure a memory cell, and the upper gate electrode 130U may be used as a gate electrode of a string select transistor. The number of the memory cell gate electrode 130M may be determined depending on the data storage capacity of the semiconductor device 10. Depending on the implementation, the lower gate electrode 130L and the upper gate electrode 130U each may be provided by one or two or more, and may have a structure the same as or different from the memory cell gate electrode 130M. In addition, a portion of the gate electrode 130, for example, the memory cell gate electrode 130M adjacent to the lower gate electrode 130L and the upper gate electrode 130U may be a dummy gate electrode.

The cell insulation layer 132 includes an interlayer insulation layer 132m located below the gate electrode 130 or between neighboring two gate electrodes 130 within the first and second gate stacked structures 120a and 120b, and upper insulation layers 132a and 132b located in upper portions of the first and second gate stacked structures 120a and 120b. For example, the upper insulation layers 132a and 132b may include a first upper insulation layer 132a located in an upper portion of a first gate stacked structure 120a, and a second upper insulation layer 132b located in an upper portion of a second gate stacked structure 120b. At this time, the first upper insulation layer 132a may be an intermediate insulation layer located between the first gate stacked structure 120a and the second gate stacked structure 120b, and the second upper insulation layer 132b may be an uppermost insulation layer located in an uppermost portion of the gate stacked structure 120. The second upper insulation layer 132b may constitute a part or all of a cell region insulation layer entirely located in an upper portion of the cell region 100. In some implementations, a thickness of a plurality of cell insulation layers 132 may not be all the same. For example, a thickness of the upper insulation layers 132a and 132b may be greater than a thickness of the interlayer insulation layer 132m. However, a shape, structure, or the like of the cell insulation layer 132 may be changed in various ways depending on implementations.

For simplicity of illustration, it is illustrated in the drawing that, in the connection region 104, the cell insulation layer 132 has a boundary between the first gate stacked structure 120a and the second gate stacked structure 120b. However, implementations are not limited thereto. In the connection region 104, a plurality of insulation layers may have various stacking structures, and implementations are not limited thereto.

The gate electrode 130 may include various conductive materials. For example, the gate electrode 130 may include a metal material such as tungsten (W), copper (Cu), aluminum (Al), or the like. As another example, the gate electrode 130 may include polysilicon, metal nitride (e.g., titanium nitride (TiN), tantalum nitride (TaN), or the like), or a combination thereof. On an outer side of the gate electrode 130, an insulation layer formed of an insulating material may be located, or a portion of the gate dielectric layer 150 may be located.

The cell insulation layer 132 may include various insulating materials. For example, the cell insulation layer 132 may include silicon oxide, silicon nitride, silicon nitride oxide, a low dielectric constant material having a smaller dielectric constant than silicon oxide or a combination thereof.

In some implementations, the channel structure CH penetrating the gate stacked structure 120 and extending the direction crossing the second substrate 110 (e.g., a vertical direction perpendicular to the second substrate 110) (Z-axis direction in the drawing) may be located.

In further detail, the channel structure CH includes the channel layer 140, and the gate dielectric layer 150 located on the channel layer 140 between the gate electrode 130 and the channel layer 140. The channel structure CH may further include a core insulation layer 142 located in an interior of the channel layer 140, and may further include a channel pad 144 disposed on the channel layer 140 and/or the gate dielectric layer 150.

Each channel structure CH may form one memory cell string, and in a plan view, a plurality of channel structures CH may be disposed to be spaced apart from each other while forming rows and columns. For example, in a plan view, the plurality of channel structures CH may be disposed in various forms such as a lattice form, a zigzag form, or the like. The channel structure CH may have a pillar shape. For example, when viewed in cross-section, the channel structure CH may have an inclined side surface such that the width becomes narrower as it is closer to the second substrate 110 depending on the aspect ratio. However, implementations are not limited thereto, and the arrangement, structure, shape, or the like of the channel structure CH may be changed in various ways.

The core insulation layer 142 may be provided in a central region of the channel structure CH, and the channel layer 140 may be provided while surrounding a sidewall of the core insulation layer 142. For example, the core insulation layer 142 may have a pillar shape (e.g., cylindrical shape or polygonal pillar shape), and the channel layer 140 may have a planar shape such as an annular shape. However, implementations are not limited thereto, and while the core insulation layer 142 is not provided, the channel layer 140 may have a pillar shape (e.g., cylindrical shape or polygonal pillar shape).

The channel layer 140 may include a semiconductor material, for example, polysilicon. The core insulation layer 142 may include various insulating materials. For example, the core insulation layer 142 may include silicon oxide, silicon nitride, silicon nitride oxide, or a combination thereof. However, the material of the channel layer 140 and the core insulation layer 142 is not limited thereto.

The gate dielectric layer 150 located between the gate electrode 130 and the channel layer 140 includes a tunneling layer 152, a charge storage layer 154 and a blocking layer 156, which are sequentially stacked on the channel layer 140.

At this time, the tunneling layer 152 may be a layer through which tunneling of charges occurs according to the voltage applied to the gate electrode 130, and may include an insulating material enabling tunneling of charges. The tunneling layer 152 may include a material such as silicon oxide, silicon nitride oxide, or the like. For example, the tunneling layer 152 may be formed by stacking a layer including silicon oxide and a layer including silicon nitride.

The charge storage layer 154 disposed between the tunneling layer 152 and the blocking layer 156 may be used as a data storage region. For example, the charge storage layer 154 may include silicon nitride capable of trapping charges. When the charge storage layer 154 is formed of silicon nitride, compared to the case of being made of polysilicon, it may provide excellent retention and may be advantageous for integration. However, the material of the charge storage layer 154 is not limited thereto.

The blocking layer 156 may be disposed between the charge storage layer 154 and the gate electrode 130. The blocking layer 156 may include an insulating material that can prevent unwanted charges from flowing into the gate electrode 130. For example, the blocking layer 156 may include silicon oxide, silicon nitride, silicon nitride oxide, high dielectric constant material or a combination thereof.

Here, high dielectric constant material may mean a dielectric material having a higher dielectric constant than silicon oxide. For example, high dielectric constant material may include aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃) or a combination thereof.

The channel pad 144 may be disposed on the channel layer 140 and/or the gate dielectric layer 150. The channel pad 144 may be disposed to cover an upper surface of the core insulation layer 142 and be electrically connected to the channel layer 140. Although it is illustrated that the channel pad 144 covers an upper surface of the gate dielectric layer 150, it is not limited thereto. For example, the channel pad 144 may not cover the upper surface of the gate dielectric layer 150. At this time, a side surface of the channel pad 144 may be surrounded by the gate dielectric layer 150. The side surface of the channel pad 144 may contact the tunneling layer 152. The channel pad 144 may include a conductive material, for example, polysilicon doped with impurities. However, the material of the channel pad 144 is not limited thereto, and may be changed in various ways.

As described above, when the gate stacked structure 120 includes the plurality of gate stacked structures 120a and 120b stacked with respect to each other, the channel structure CH may be provided with the plurality of channel structures CH1 and CH2 that penetrate the plurality of gate stacked structures 120a and 120b, respectively. The plurality of channel structures CH1 and CH2 may have a form to be interconnected. When viewed in cross-section, each of the plurality of channel structures CH1 and CH2 may have an inclined side surface such that the width becomes narrower as it is closer to the second substrate 110 depending on the aspect ratio. As shown in FIG. 2, by a difference of width in a portion where the plurality of channel structures CH1 and CH2 are connected, a bent portion may be provided. As another example, as shown in FIG. 3, a first channel structure CH1 and a second channel structure CH2 may be provided with an inclined side surface that is continuous without a bent portion. However, a shape of the plurality of channel structures CH1 and CH2 is not limited thereto, and may be changed in various ways.

FIG. 1 illustrates, as an example, an integral structure in which the gate dielectric layer 150, the channel layer 140 and the core insulation layer 142 of each of the plurality of channel structures CH1 and CH2 are formed by extending. However, implementations are not limited thereto. As another example, the gate dielectric layer 150, the channel layer 140 and the core insulation layer 142 of each of the plurality of channel structures CH1 and CH2 may be separately formed and electrically connected to each other.

In addition, a separate channel pad may be additionally provided to a connection portion of the plurality of channel structures CH1 and CH2. Various other changes are available.

In some implementations, in a plan view, the gate stacked structure 120 may be partitioned into a plural quantity by a separation structure 146 extending the direction crossing the second substrate 110 (e.g., a perpendicular direction, Z-axis direction of the drawing) to penetrate the gate stacked structure 120.

For example, the separation structure 146 may penetrate the gate electrode 130 and the cell insulation layer 132 and extend to the second substrate 110. In a plan view, the separation structure 146 may be provided in a plural quantity such that they may extend in one direction (Y-axis direction in the drawing) and may be spaced apart from each other with a preset interval in a crossing direction (X-axis direction in the drawing) crossing the one direction. Accordingly, in a plan view, the plurality of gate stacked structures 120 may extend in one direction (Y-axis direction in the drawing), respectively, and may be spaced apart from each other with a preset interval in a crossing direction (X-axis direction in the drawing). The gate stacked structure 120 partitioned by the separation structure 146 may configure one memory cell block. However, implementations are not limited thereto, and the range of the memory cell block is not limited thereto.

When viewed in cross-section, as an example, the separation structure 146 may have an inclined side surface of which a width decreases toward the second substrate 110 due to the high aspect ratio. However, implementations are not limited thereto, and a side surface of the separation structure 146 may be perpendicular to the second substrate 110. When viewed in cross-section, FIG. 2 illustrates an example in which the separation structure 146 has a continuous inclined side surface in the first gate stacked structure 120a and the second gate stacked structure 120b and is not provided with a bent portion. However, implementations are not limited thereto, and the separation structure 146 may be provided with a bent portion in a boundary portion between the first gate stacked structure 120a and the second gate stacked structure 120b.

The separation structure 146 may be filled with various insulating materials. For example, the separation structure 146 may include an insulating material such as silicon oxide, silicon nitride, or silicon nitride oxide. However, implementations are not limited thereto, and the structure, shape, material, or the like of the separation structure 146 may change in various ways.

In addition, an upper separation pattern 148 may be formed in an upper portion of the gate stacked structure 120. In a plan view, the upper separation pattern 148 may be provided in a plural quantity such that they may extend in one direction (Y-axis direction in the drawing) and may be spaced apart from each other with a preset interval in a crossing direction (X-axis direction in the drawing) crossing the one direction.

The upper separation pattern 148 may be formed to penetrate one or a plurality of gate electrodes 130 including the upper gate electrode 130U located between the separation structures 146. The upper separation pattern 148 may separate, for example, three gate electrodes 130, from each other in the crossing direction (X-axis direction in the drawing). However, the number of the gate electrodes 130 separated by the upper separation pattern 148 is not limited thereto, and may be changed in various ways. The upper separation pattern 148 may have the form filled with an insulating material. For example, the upper separation pattern 148 may include an insulating material such as silicon oxide, silicon nitride, or silicon nitride oxide. However, implementations are not limited thereto, and the structure, shape, material, or the like of the upper separation pattern 148 may be changed in various ways.

In order to connect the gate stacked structure 120 and the channel structure CH provided in the cell array region 102 to the circuit region 200 or external circuit, the connection region 104 and a connection portion 180 may be provided.

Here, the connection portion 180 may include all members configured to electrically connect the gate electrode 130, the channel structure CH, the horizontal conductive layers 112 and 114 and/or the second substrate 110 to the circuit region 200 or external circuit. For example, the connection portion 180 may include a bit line 182, a gate contact portion 184, a source contact portion 186, and a contact via 180a connected thereto, and the second wiring portion 190 connecting them.

The bit line 182 may be located on the cell insulation layer 132 of the gate stacked structure 120 formed in the cell array region 102. The bit line 182 may extend in a crossing direction (X-axis direction in the drawing) crossing one direction along which the gate electrode 130 extends. The bit line 182 may be electrically connected to the channel structure CH, for example, the channel pad 144 through the contact via 180a, for example, a bit line contact via.

The connection region 104 may be disposed in the vicinity of the cell array region 102. A portion of the connection portion 180 may be located in the connection region 104. The gate electrode 130, the horizontal conductive layers 112 and 114 and/or the second substrate 110, and members for connection to the circuit region 200 may be provided in the connection region

In further detail, in the connection region 104, the plurality of gate electrodes 130 may be located to extend in one direction (Y-axis direction in the drawing), and in the connection region 104, an extension length of the plurality of gate electrodes 130 may sequentially decrease away from the second substrate 110. For example, the plurality of gate electrodes 130 may be located in the connection region 104 in a step shape. At this time, the plurality of gate electrodes 130 may have a step shape in one direction or a plurality of directions. In the connection region 104, a plurality of gate contact portions 184 may be electrically connected to the plurality of gate electrodes 130 that penetrate the cell insulation layer 132 to extend in the connection region 104, respectively.

FIG. 1 illustrates an example in which, in the connection region 104, the gate contact portion 184 penetrates the cell insulation layer 132 to reach the gate electrode 130 and be connected to the gate electrode 130. However, it is not limited thereto, and the gate contact portion 184 may penetrate the cell insulation layer 132 and the gate electrode 130 and extend to the first wiring portion 230 provided in the circuit region 200. At this time, the gate contact portion 184 may be provided with a pad to correspond to the gate electrode 130 to be connected among the plurality of gate electrodes 130 included in the gate stacked structure 120, and may be insulated from another gate electrode 130 by an insulating material.

In the connection region 104, the source contact portion 186 may penetrate the cell insulation layer 132 and electrically connected to the horizontal conductive layers 112 and 114 and/or the second substrate 110.

When viewed in cross-section, FIG. 1 illustrates an example in which the gate contact portion 184 and/or the source contact portion 186 may have an inclined side surface such that the width becomes narrower as it is closer to the second substrate 110 depending on the aspect ratio, and a bent portion is provided in a boundary portion between the first gate stacked structure 120a and the second gate stacked structure 120b. However, implementations are not limited thereto. For example, it is also possible that the gate contact portion 184 and/or the source contact portion 186 is not provided with a bent portion in a boundary portion between the first gate stacked structure 120a and the second gate stacked structure 120b. Various other changes are available.

The second wiring portion 190 may be located in the cell array region 102 and/or the connection region 104. The bit line 182, the gate contact portion 184, and/or the source contact portion 186 may be electrically connected to the second wiring portion 190. For example, the gate contact portion 184 and/or the source contact portion 186 may be connected to the second wiring portion 190 through the contact via 180a.

In some implementations, the second wiring portion 190 includes a plurality of second wire layers 196 spaced apart from each other interposing a second insulation layer 192 and connected by a second contact 194. The second wire layer 196 or the second contact 194 may include various conductive materials, and the second insulation layer 192 may include various insulating materials.

According to some implementations, the connection portion 180 includes a connection contact structure CC and a dummy contact structure DC. The connection contact structure CC may be located on an outer side of the gate stacked structure 120 in the connection region 104. Although FIG. 1 illustrates one connection contact structure CC, it is not limited thereto, and a plurality of connection contact structures CC may be disposed to be spaced apart in direction parallel to an upper surface of the first substrate 210 on the outer side of the gate stacked structure 120 in the connection region 104. The connection contact structure CC may penetrate the upper insulation layers 132a and 132b that cover an upper surface of the gate stacked structure 120 and the first wiring portion 230.

The connection contact structure CC may penetrate the first upper insulation layer 132a located in an upper portion of the first gate stacked structure 120a and the second upper insulation layer 132b located in the upper portion of the second gate stacked structure 120b. FIG. 1 illustrates an example in which a boundary exists between the first upper insulation layer 132a and the second upper insulation layer 132b, but is not limited thereto. In the connection region 104, insulation layer located on the outer side of the gate stacked structure 120 may have a single layer or various stacking structures.

The connection contact structure CC may penetrate the upper insulation layers 132a and 132b and be connected to the circuit element 220. By the connection portion 180 and the first wiring portion 230 including the connection contact structure CC, the bit line 182, the gate electrode 130, the horizontal conductive layers 112 and 114 and/or the second substrate 110, which are connected to the channel structure CH may be electrically connected to the circuit element 220 of the circuit region 200.

The connection contact structure CC includes a connection contact CT configured to connect a plurality of connection wire layers CW located in upper and lower portions of the upper insulation layers 132a and 132b in direction perpendicular to the upper surface of the first substrate 210. The plurality of connection wire layers CW include a plurality of lower connection wire layers 250 located in a lower portion of the upper insulation layers 132a and 132b and a plurality of upper connection wire layers 160 located in an upper portion of the upper insulation layers 132a and 132b.

The plurality of lower connection wire layers 250 may be disposed to be spaced apart in a direction (Z direction) perpendicular to the first substrate 210 by the first insulation layer 232 of the first wiring portion 230. The plurality of lower connection wire layers 250 may be respectively located in the same layer as a plurality of wire layer 236 of the first wiring portion 230. The plurality of lower connection wire layers 250 may be connected to the plurality of wire layer 236 of the first wiring portion 230.

The plurality of upper connection wire layers 160 may be disposed to be spaced apart in a direction (Z direction) perpendicular to the first substrate 210 by the second insulation layer 192 of the second wiring portion 190. The plurality of upper connection wire layers 160 may be located in the same layer as the plurality of second wire layers 196 of the second wiring portion 190, respectively. The plurality of upper connection wire layers 160 may be connected to the plurality of second wire layers 196 of the second wiring portion 190.

The connection contact CT includes a lower contact 187 connecting the plurality of lower connection wire layers 250 or the lower connection wire layer 250 and the circuit element 220, an upper contact 189 connecting the plurality of upper connection wire layers 160, and a through-contact 188 connecting the lower connection wire layer 250 and the upper connection wire layer 160.

The lower contact 187 may connect the plurality of lower connection wire layers 250 by penetrating the first insulation layer 232 of the first wiring portion 230, or may connect the lower connection wire layer 250 and the circuit element 220. The upper contact 189 may connect the plurality of upper connection wire layers 160 by penetrating the second insulation layer 192 of the second wiring portion 190.

FIG. 1 illustrates an example in which the upper contact 189 connects the plurality of upper connection wire layers 160, but is not limited thereto. The connection region 104 may include an input/output pad on the second wiring portion 190, and the upper contact 189 may connect the upper connection wire layer 160 and the input/output pad. The plurality of connection wire layers CW connected to the input/output pad may include an input/output connection wire.

The through-contact 188 may penetrate the upper insulation layers 132a and 132b and be connected to the lower connection wire layer 250. The through-contact 188 may be directly connected to the lower connection wire layer 250. The through-contact 188 may connect the lower connection wire layer 250 and the upper connection wire layer 160. FIG. 1 illustrates an example in which the through-contact 188 is connected to the upper connection wire layer 160 through the contact via 180a, but is not limited thereto.

When viewed in cross-section, in FIG. 1 and FIG. 4, the connection contact CT may have an inclined side surface such that the width becomes narrower as it is closer to the first substrate 210 depending on the aspect ratio. The through-contact 188 may be provided with a bent portion in a boundary portion between the first upper insulation layer 132a and the second upper insulation layer 132b, but is not limited thereto. For example, the through-contact 188 may not be provided with a bent portion in the boundary portion between the first upper insulation layer 132a and the second upper insulation layer 132b, and various other changes are available.

The plurality of connection wire layers CW and the connection contact CT may include a conductive material. For example, the plurality of connection wire layers CW may include a metal, but is not limited thereto. The connection contact CT may include the same material as the plurality of connection wire layers CW, and may include a conductive material different from the material of the plurality of connection wire layers CW. The lower contact 187, the through-contact 188, and the upper contact 189 may include different materials, respectively.

The connection contact structure CC may electrically connect the first wire layer 236 connected to the lower connection wire layer 250 and the second wire layer 196 connected to the upper connection wire layer 160. The connection contact structure CC may be electrically connected to the circuit element 220 connected to the lower connection wire layer 250. For example, when the connection contact CT is further connected to the input/output pad, the connection contact structure CC may be electrically connected to the input/output pad.

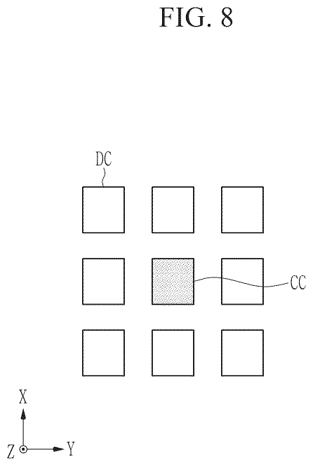

The dummy contact structure DC may be disposed adjacent to the connection contact structure CC. A plurality of dummy contact structures DC may be disposed adjacent to the connection contact structure CC. The arrangement of the plurality of dummy contact structures DC and the connection contact structure CC will be described later in detail with reference to FIG. 8 to FIG. 12.

The dummy contact structure DC includes a dummy contact DCT overlapping with the connection contact CT in a direction parallel to the upper surface of the first substrate 210. The dummy contact DCT may extend in a direction perpendicular to the upper surface of the first substrate 210.

According to some implementations, the dummy contact DCT may overlap with the through-contact 188 in a direction parallel to the upper surface of the first substrate 210. The dummy contact DCT may penetrate the upper insulation layers 132a and 132b. In some implementations, the dummy contact DCT may be provided with a bent portion in the boundary portion between the first upper insulation layer 132a and the second upper insulation layer 132b, but is not limited thereto. For example, the dummy contact DCT may not be provided with a bent portion in the boundary portion between the first upper insulation layer 132a and the second upper insulation layer 132b, and Various other changes are available.

The dummy contact structure DC may have a lower dielectric constant than the connection contact structure CC. The dummy contact structure DC may include a different material from the connection contact structure CC. The dummy contact structure DC may include a material having a lower dielectric constant than the connection contact structure CC. According to some implementations, the dummy contact DCT may include a material having a lower dielectric constant than the connection contact CT overlapping with the dummy contact DCT in a direction parallel to the upper surface of the first substrate 210. In FIG. 1 and FIG. 4, since the dummy contact DCT overlaps with the through-contact 188 in a direction parallel to the upper surface of the first substrate 210, the dummy contact DCT may include a material having a lower dielectric constant than the through-contact 188.

A material having a lower dielectric constant than the connection contact CT may include, for example, air, but is not limited thereto. The dummy contact DCT may include an insulating property material, but it is not limited thereto, and may include a conductive material having a lower conductivity than the connection contact CT.

According to some implementations, the dummy contact DCT includes a cover layer CV and an air gap AG located within the cover layer CV. The cover layer CV may surround the air gap AG. In FIG. 1 and FIG. 4, the cover layer CV may separate the air gap AG from the upper insulation layers 132a and 132b.

In some implementations, the cover layer CV may include the same material as the connection contact CT. However, implementations are not limited to the case that the cover layer CV includes the same material as the connection contact CT. In some implementations, the cover layer CV may include a different material from the connection contact CT. At this time, material different from the connection contact CT may include a material having a lower dielectric constant than the connection contact CT, or a material having a higher dielectric constant than the connection contact CT. For example, when the cover layer CV includes a material having a higher dielectric constant than the connection contact CT, the entire dummy contact DCT, including the cover layer CV and the air gap AG, may have a lower dielectric constant than the connection contact CT.

The dummy contact structure DC may be floating. FIG. 1 and FIG. 4 illustrate that the dummy contact DCT is connected to the lower connection wire layer 250 and an upper connection wire layer 150, being directly connected to the lower connection wire layer 250, and connected to the upper connection wire layer 150 through the contact via 180a. However, implementations are not limited thereto, and the dummy contact DCT may not be connected to the lower connection wire layer 250 and the upper connection wire layer 150. Alternatively, the dummy contact DCT may not be electrically connected to the lower connection wire layer 250 and the upper connection wire layer 150. For example, the wire of the lower connection wire layer 250 and the wire of the upper connection wire layer 150 to which the dummy contact DCT is connected may not be connected to other wires of the lower connection wire layer 250 and the upper connection wire layer 150. As another example, as the dummy contact DCT includes an insulative material, it may not be electrically connected to the lower connection wire layer 250 and the upper connection wire layer 150.

The semiconductor device 10 according to some implementations includes the dummy contact structure DC adjacent to the connection contact structure CC and having a lower dielectric constant than the connection contact structure CC, and thereby, in a direction parallel to the upper surface of the first substrate 210, parasitic capacitance of the connection contact structure CC may decrease.

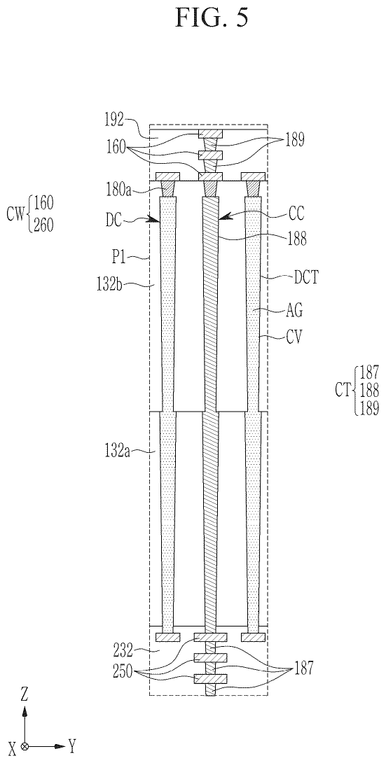

Hereinafter, various examples of the dummy contact structure DC of the semiconductor device 10 of FIG. 1 will be described with reference to FIG. 5 to FIG. 7.

FIG. 5 to FIG. 7 are drawings showing various examples of a dummy contact structure of a semiconductor device according to some implementations. FIG. 5 to FIG. 7 may be enlarged cross-sectional views of P1 of FIG. 1.

Referring to FIG. 5, as in the implementations of FIG. 4, the dummy contact structure DC may be disposed adjacent to the connection contact structure CC. The dummy contact structure DC includes the dummy contact DCT overlapping with the connection contact CT in a direction parallel to an upper surface of the substrate 210 (see FIG. 1). The dummy contact DCT may connect the upper connection wire layer 160 and the lower connection wire layer 250 by penetrating the upper insulation layers 132a and 132b. The dummy contact DCT may overlap with the through-contact 188 in a direction parallel to the upper surface of the substrate 210 (see FIG. 1).

According to the implementations shown in FIG. 5, unlike the implementations of FIG. 4, the dummy contact DCT may have the same cross-section shape as the connection contact CT. The dummy contact DCT may include a material having a lower dielectric constant than the connection contact CT. According to some implementations, the dummy contact DCT may have the same cross-section shape as the through-contact 188. The dummy contact DCT may not include an air gap, and its interior may be completely filled with a material having a lower dielectric constant than the material forming the through-contact 188.

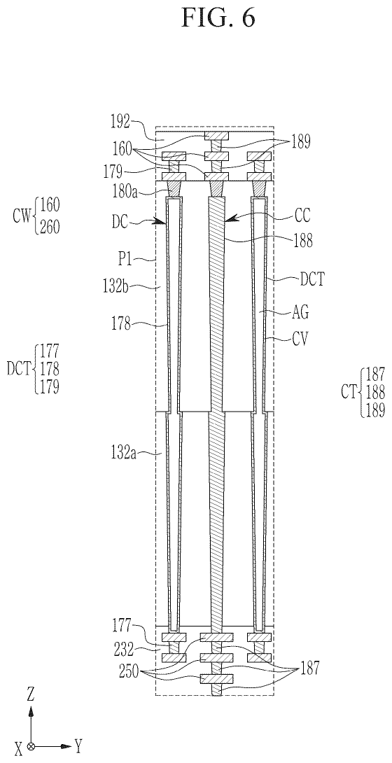

According to some implementations, in a direction parallel to the upper surface of the substrate 210 (see FIG. 1), parasitic capacitance of the through-contact 188 may be reduced. Referring to FIG. 6, as in the implementations of FIG. 4, the dummy contact structure

DC may be disposed adjacent to the connection contact structure CC. The dummy contact structure DC includes the dummy contact DCT overlapping with the connection contact CT in a direction parallel to the upper surface of the substrate 210 (see FIG. 1). The dummy contact DCT may penetrate the upper insulation layers 132a and 132b to extend in a direction perpendicular to the upper surface of the substrate 210 (see FIG. 1). The dummy contact DCT may overlap with the through-contact 188 in a direction parallel to the upper surface of the substrate 210 (see FIG. 1).

According to the implementations shown in FIG. 6, unlike the implementations of FIG. 4, the dummy contact DCT may further overlap with the lower contact 187 connecting the plurality of lower connection wire layers 250 by penetrating the first insulation layer 232 in a direction parallel to the upper surface of the substrate 210 (see FIG. 1). The dummy contact DCT may further overlap with the upper contact 189 connecting the plurality of upper connection wire layers 160 by penetrating the second insulation layer 192 in a direction parallel to the upper surface of the substrate 210 (see FIG. 1). FIG. 6 illustrates an example in which the dummy contact DCT overlaps with the through-contact 188 in a direction parallel to the upper surface of the substrate 210 (see FIG. 1), and further overlaps with the lower contact 187 and the upper contact 189, but implementations are not limited thereto. For example, the dummy contact DCT may overlap with the through-contact 188 in a direction parallel to the upper surface of the substrate 210 (see FIG. 1), and may further overlap with one of the lower contact 187 and the upper contact 189.

According to some implementations, the dummy contact DCT includes a penetration dummy contact 178 overlapping with the through-contact 188 in a direction parallel to the upper surface of the substrate 210 (see FIG. 1), and includes at least one of a lower dummy contact 177 overlapping with the lower contact 187 in a direction parallel to the upper surface of the substrate 210 (see FIG. 1) or an upper dummy contact 179 overlapping with the upper contact 189 in a direction parallel to the upper surface of the substrate 210 (see FIG. 1).

According to some implementations, the penetration dummy contact 178 may have a different internal structure from the through-contact 188, and the lower dummy contact 177 and the upper dummy contact 179 may have the same internal structure as the lower contact 187 and the upper contact 189, respectively. According to some implementations, the penetration dummy contact 178 includes the cover layer CV including the same material as the through-contact 188 and the air gap AG located within the cover layer CV, but is not limited thereto. For example, the cover layer CV of the penetration dummy contact 178 may include a different material from the through-contact 188. At this time, material different from the through-contact 188 may include a material having a lower dielectric constant than the through-contact 188, or a material having a higher dielectric constant than the through-contact 188. For example, when the cover layer CV of the penetration dummy contact 178 includes a material having a higher dielectric constant than the through-contact 188, the entire penetration dummy contact 178, including the cover layer CV and the air gap AG, may have a lower dielectric constant than the through-contact 188.

According to some implementations, the lower dummy contact 177 and the upper dummy contact 179 may have the same cross-section shape as the lower contact 187 and the upper contact 189, respectively. The lower dummy contact 177 and the upper dummy contact 179 may be completely filled with the same material as the material forming the lower contact 187 and the upper contact 189, respectively.

However, implementations are not limited to case that only the penetration dummy contact 178 has a lower dielectric constant than the through-contact 188. According to some implementations, the lower dummy contact 177 and the upper dummy contact 179 may also have lower dielectric constants than the lower contact 187 and the upper contact 189, respectively. For example, the lower dummy contact 177 and the upper dummy contact 179 may be completely filled with a material having a lower dielectric constant forming the lower contact 187 and the upper contact 189, respectively. At this time, the lower dummy contact 177 and the upper dummy contact 179 may include different materials. As another example, the lower dummy contact 177 and the upper dummy contact 179 may include the air gap AG located in the cover layer CV and the cover layer CV, respectively. At this time, the cover layer CV of the lower dummy contact 177 may include a material the same as or similar to the lower contact 187. At this time, material different from the lower contact 187 may include a material having a lower or a higher dielectric constant than the lower contact 187. When the cover layer CV of the lower dummy contact 177 includes a material having a higher dielectric constant than the lower contact 187, the entire lower dummy contact 177 including the cover layer CV and the air gap AG may have a lower dielectric constant than the lower contact 187. The content described above with respect to the cover layer CV of the lower dummy contact 177 may be applied identically or similarly to the cover layer CV of the upper dummy contact 179.

FIG. 6 illustrates an example in which the dummy contact DCT includes one lower dummy contact 177 and one upper dummy contact 179, but is not limited thereto. The dummy contact DCT may include a plurality of lower dummy contacts 177 or a plurality of upper dummy contacts 179.

According to some implementations, in a direction parallel to the upper surface of the substrate 210 (see FIG. 1), parasitic capacitance of the through-contact 188 may be reduced. According to some implementations in which the lower dummy contact 177 and the upper dummy contact 179 further have a lower dielectric constant than the lower contact 187 and the upper contact 189, parasitic capacitance of the lower contact 187 and the upper contact 189 may be further reduced.

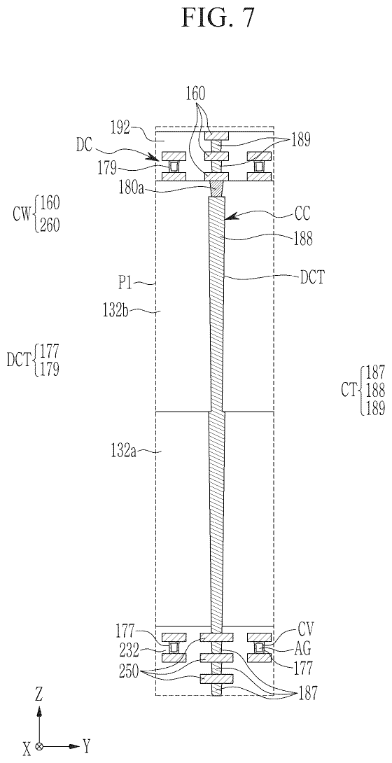

Referring to FIG. 7, as in the implementations of FIG. 4, the dummy contact structure DC may be disposed adjacent to the connection contact structure CC. The dummy contact structure DC includes the dummy contact DCT overlapping with the connection contact CT in a direction parallel to the upper surface of the substrate 210 (see FIG. 1).

According to the implementations shown in FIG. 7, unlike the implementations of FIG. 4, the dummy contact DCT may overlap with the lower contact 187 connecting the plurality of lower connection wire layers 250 by penetrating the first insulation layer 232, in a direction parallel to the upper surface of the substrate 210 (see FIG. 1). The dummy contact DCT may overlap with the upper contact 189 connecting the plurality of upper connection wire layers 160 by penetrating the second insulation layer 192, in a direction parallel to the upper surface of the substrate 210 (see FIG. 1). According to some implementations, the dummy contact DCT may not penetrate the upper insulation layers 132a and 132b.

According to some implementations, the dummy contact DCT may include the lower dummy contact 177 overlapping with the lower contact 187 in a direction parallel to the upper surface of the substrate 210 (see FIG. 1) or at least one of the upper dummy contact 179 overlapping with the upper contact 189 in a direction parallel to the upper surface of the substrate 210 (see FIG. 1).

FIG. 7 illustrates an example in which the dummy contact DCT includes all of the lower dummy contact 177 and the upper dummy contact 179, but is not limited thereto, and the dummy contact DCT may include only one of the lower dummy contact 177 or the upper dummy contact 179.

According to some implementations, the lower dummy contact 177 and the upper dummy contact 179 may have different internal structures from the lower contact 187 and the upper contact 189, respectively. According to some implementations, the lower dummy contact 177 and the upper dummy contact 179 includes the air gap AG located in the cover layer CV and the cover layer CV, respectively. The cover layer CV of the lower dummy contact 177 may include a material the same as or similar to the lower contact 187. At this time, material different from the lower contact 187 may include a material having a lower or a higher dielectric constant than the lower contact 187. When the cover layer CV of the lower dummy contact 177 includes a material having a higher dielectric constant than the lower contact 187, the entire lower dummy contact 177 including the cover layer CV and the air gap AG may have a lower dielectric constant than the lower contact 187. The content described above with respect to the cover layer CV of the lower dummy contact 177 may be applied identically or similarly to the cover layer CV of the upper dummy contact 179.

However, the present disclosure is not limited to the above-described implementations. According to some implementations, the lower dummy contact 177 and the upper dummy contact 179 may be completely filled with a material having a lower dielectric constant forming the lower contact 187 and the upper contact 189, respectively. At this time, the lower dummy contact 177 and the upper dummy contact 179 may include different materials.

According to some implementations, the lower dummy contact 177 includes the air gap AG located in the cover layer CV and the cover layer CV, and the upper dummy contact 179 may be completely filled with a material having a lower dielectric constant forming the upper contact 189. Some implementations in which the structure of the lower dummy contact 177 and the structure of the upper dummy contact 179 are opposite may be possible.

According to some implementations, the lower dummy contact 177 may have a lower dielectric constant than the lower contact 187, and the upper dummy contact 179 may have the same dielectric constant as the upper contact 189. In other implementations, the upper dummy contact 179 may have a lower dielectric constant than the upper contact 189, and the lower dummy contact 177 may have the same dielectric constant as the lower contact 187. That is, it is sufficient if at least one of the lower dummy contact 177 or the upper dummy contact 179 included by the dummy contact DCT has a lower dielectric constant than the lower contact 187 or the upper contact 189 overlapping with it.

FIG. 7 illustrates an example in which the dummy contact DCT includes one lower dummy contact 177 and one upper dummy contact 179, but is not limited thereto. The dummy contact DCT may include the plurality of lower dummy contacts 177, or may include the plurality of upper dummy contacts 179. The numbers of the lower dummy contact 177 and the upper dummy contact 179 included in the dummy contact DCT may be different. When the dummy contact DCT includes the plurality of lower dummy contacts 177, the lower dummy contacts 177 including a different material or having a different structure may be included. When the dummy contact DCT includes the plurality of upper dummy contacts 179, the upper dummy contacts 179 including a different material or having a different structure may be included. At least one lower dummy contact 177 or at least one upper dummy contact 179 may have a lower dielectric constant than the lower contact 187 or the upper contact 189 overlapping with it.

According to some implementations, in a direction parallel to the upper surface of the substrate 210 (see FIG. 1), parasitic capacitance of the lower contact 187 and/or the upper contact 189 may be reduced.

Hereinafter, referring to FIG. 8 to FIG. 12, the arrangement in a plan view of the connection contact structure CC and the dummy contact structure DC of the semiconductor device 10 of FIG. 1 will be described.

FIG. 8 to FIG. 12 are drawings showing various examples of an arrangement in a plan view of a connection contact structure and a dummy contact structure of a semiconductor device according to some implementations. FIG. 8 to FIG. 12 may represent the arrangement of the connection contact CT (see FIG. 1) and the dummy contact DCT (see FIG. 1) overlapping in a direction parallel to the upper surface of the substrate 210 (see FIG. 1). Although FIG. 8 to FIG. 12 illustrate that the planar shape of the connection contact CT (see FIG. 1) and the dummy contact DCT (see FIG. 1) is quadrangular, it may be understood that this is represented in an arbitrary shape in order to represent the arrangement relationship between the connection contact CT (see FIG. 1) and the dummy contact DCT (see FIG. 1), and the planar shape of the connection contact CT (see FIG. 1) and the dummy contact DCT (see FIG. 1) may be changed in various ways.

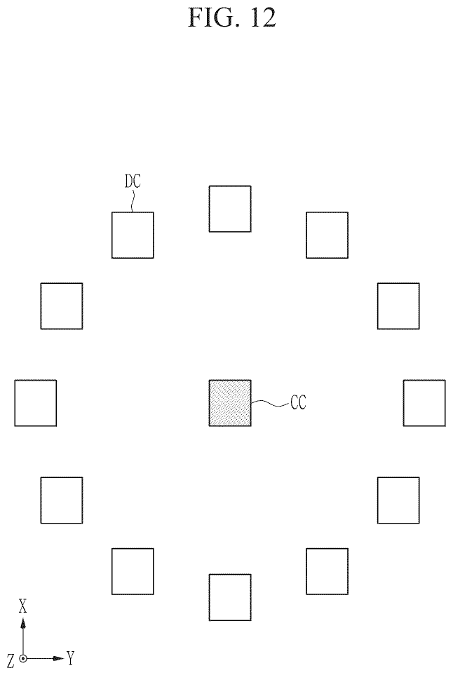

Referring to FIG. 8 to FIG. 12, the plurality of dummy contact structures DC may be disposed adjacent to the connection contact structure CC. In a plan view, the plurality of dummy contact structures DC may be disposed to surround the connection contact structure CC. FIG. 8 to FIG. 11 illustrate an example in which the plurality of dummy contact structures DC surrounding the connection contact structure CC are disposed in a quadrangular shape, but is not limited thereto, and as shown in FIG. 12, they may be circularly disposed. In addition, an arrangement in a plan view of the plurality of dummy contact structures DC may be changed to various forms.

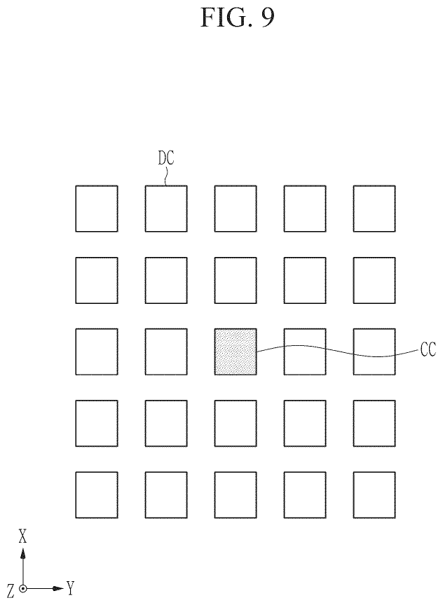

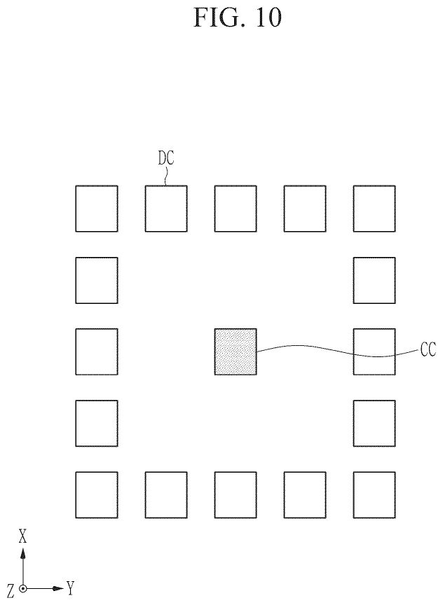

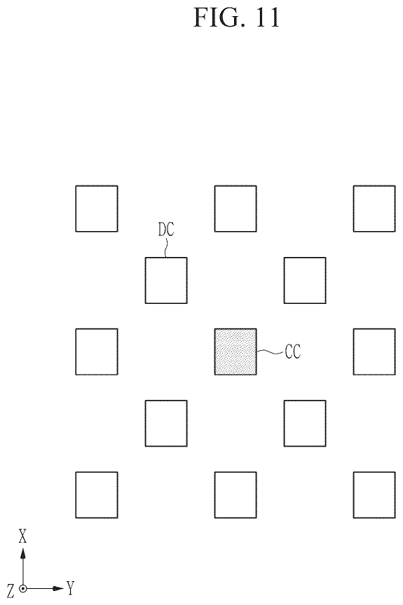

As shown in FIG. 8, FIG. 10 and FIG. 12, the plurality of dummy contact structures DC may be disposed to surround the connection contact structure CC once. Alternatively, as shown in FIG. 9 and FIG. 11, the plurality of dummy contact structures DC may be disposed to surround the connection contact structure CC twice. As such, the plurality of dummy contact structures DC may be disposed to surround the connection contact structure CC once or more times. That is, one or more dummy contact structures DC may be further located between the connection contact structure CC and the dummy contact structure DC.

FIG. 8, FIG. 10 and FIG. 12 illustrate an example in which adjacent dummy contact structures DC are disposed to be spaced apart from each other at the same interval, but is not limited thereto. In some implementations, the adjacent dummy contact structures DC may be spaced apart in different intervals to be disposed irregularly.

The distance at which the plurality of dummy contact structures DC are spaced apart from the connection contact structure CC may be changed in various ways as shown in FIG. 8 and FIG. 10. FIG. 9 and FIG. 11 illustrate an example that the plurality of dummy contact structures DC may include first dummy contact structures surrounding the connection contact structure CC at location spaced apart from the connection contact structure CC by about a first distance, and second dummy contact structures surrounding the connection contact structure CC at a location spaced apart from the connection contact structure CC by about a second distance. At this time, the first distance and the second distance may be changed in various ways.

In a plan view, a first one of the plurality of dummy contact structures DC may be disposed on a first side of the connection contact structure CC, and a second one may be disposed on an opposite side of the connection contact structure CC. For example, as shown in FIG. 8, FIG. 10 and FIG. 12, one dummy contact structure DC may be disposed on one side and an opposite side of the connection contact structure CC, respectively. For example, as shown in FIG. 9 and FIG. 11, two dummy contact structures DC may be disposed on one side and an opposite side of the connection contact structure CC, respectively. That is, the connection contact structure CC may be located between at least two dummy contact structures DC. FIG. 8 to FIG. 12 illustrate an example in which the number of the dummy contact structures DC located on the first side of the connection contact structure CC and the number of the dummy contact structures DC located on the opposite side are the same, but is not limited thereto. In some implementations, the number of the dummy contact structures DC located on the first side of the connection contact structure CC and the number of the dummy contact structures DC located on the opposite side may be different.

Meanwhile, FIG. 8 to FIG. 12 illustrate an example in which the plurality of dummy contact structures DC are disposed to surround one connection contact structure CC, but is not limited thereto. For example, the plurality of dummy contact structures DC may be disposed to surround the plurality of connection contact structures CC. For example, the plurality of connection contact structures CC may be disposed in the form of an array, but is not limited thereto. Different voltages may be applied to the plurality of connection contact structures CC disposed to be surrounded by the plurality of dummy contact structures DC, respectively.

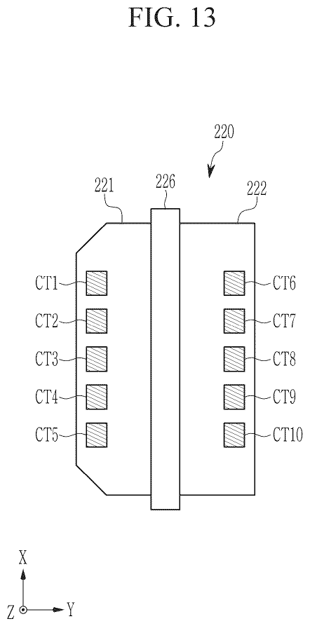

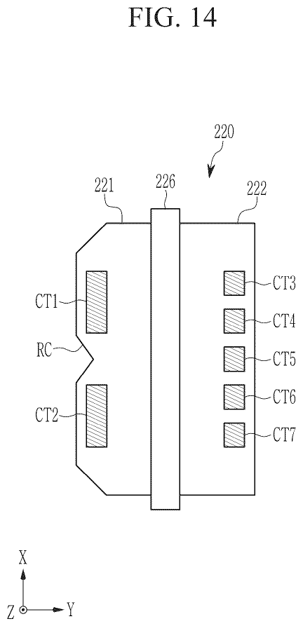

Hereinafter, referring to FIG. 13 and FIG. 14, various planar shapes of the active region of the circuit element 220 to which the connection contact structure CC of the semiconductor device 10 of FIG. 1 is connected will be described.

FIG. 13 and FIG. 14 are plan views showing various examples of a circuit element connected to a connection contact structure of a semiconductor device according to some implementations. The circuit element 220 shown in FIG. 13 and FIG. 14 may be, for example, a transistor.

The circuit element 220 includes a plurality of active regions 221 and 222 located on an inner side from the surface of the substrate 210 (see FIG. 1) and a peripheral circuit gate electrode 226 located between the plurality of active regions 221 and 222 on the substrate 210 (see FIG. 1). The plurality of active regions 221 and 222 include a first active region 221 and a second active region 222. For example, the first active region 221 may be a source region, and the second active region 222 may be a drain region. As another example, the first active region 221 may be a drain region, and the second active region 222 may be a source region.

Referring to FIG. 13, first to fifth connection contacts CT1, CT2, CT3, CT4, and CT5 may be connected to the first active region 221, and sixth to tenth connection contacts CT6, CT7, CT8, CT9, and CT10 may be connected to the second active region 222. The first to fifth connection contacts CT1, CT2, CT3, CT4, and CT5 may be connection contacts to which the same voltage is applied. The sixth to tenth connection contacts CT6, CT7, CT8, CT9, and CT10 may be connection contacts to which the same voltage is applied. Different voltages may be applied to the first to fifth connection contacts CT1, CT2, CT3, CT4, and CT5 and the sixth to tenth connection contacts CT6, CT7, CT8, CT9, and CT10.

Referring to FIG. 13, in a plan view, at least one active region among the plurality of active regions 221 and 222 may have a quadrangular shape of which at least one corner portion is chamfered. According to some implementations, the planar shape of at least one active region, among the plurality of active regions 221 and 222, whose influence on the electric characteristics or performance of the circuit element 220 is lower than a designated level may be in a quadrangular shape of which at least one corner portion is chamfered. FIG. 13 illustrates an example in which the first active region 221 may have a quadrangular shape of which at least one corner portion is chamfered, and the second active region 222 may have a quadrangular shape. At this time, the first active region 221 may be an active region that has less influence on the electric characteristics or performance of the circuit element 220 compared to the second active region 222.

However, implementations are not limited to the example shown in FIG. 13, and according to some implementations, the planar shape of each of the first active region 221 and the second active region 222 may be a quadrangular shape of which at least one corner portion is chamfered. In addition, the number and area of the corner portion of which each active region is chamfered may be changed in various ways.

According to some implementations, in comparison with Comparative Example in which the planar shape of the active region is a quadrangular shape of which the corner portion is not chamfered, the area of the active region may be small. As the area of the active region is smaller, the junction capacitance of the circuit element 220 may decrease.

According to the implementations shown in FIG. 14, as in the implementations shown in FIG. 13, the circuit element 220 includes the plurality of active regions 221 and 222 located in an inner side from the surface of the substrate (e.g., the first substrate 210 of FIG. 1), and the peripheral circuit gate electrode 226 located between the plurality of active regions 221 and 222 on the substrate 210 (see FIG. 1). The plurality of active regions 221 and 222 includes the first active region 221 and the second active region 222.

Referring to FIG. 14, first and second connection contacts CT1 and CT2 may be connected to the first active region 221, and third to seventh connection contacts CT3, CT4, CT5, CT6, and CT7 may be connected to the second active region 222. First and second contacts CT1 and CT2 may be connection contacts to which the same voltage is applied. The third to seventh connection contacts CT3, CT4, CT5, CT6, and CT7 may be connection contacts to which the same voltage is applied. Different voltages may be applied to the first and second contacts CT1 and CT2 and the third to seventh connection contacts CT3, CT4, CT5, CT6, and CT7.

In a plan view, the first and second contacts CT1 and CT2 may have a shape extending in a direction (X direction) along which the peripheral circuit gate electrode 226 extends, but it is not limited thereto, and the planar shape of each of the first to seventh connection contacts CT1, CT2, CT3, CT4, CT5, CT6, and CT7 may be changed in various ways.

According to the implementations shown in FIG. 14, unlike the implementations shown in FIG. 13, in a plan view, at least one active region among the plurality of active regions 221 and 222 may include a recess RC on an edge. According to some implementations, at least one active region, among the plurality of active regions 221 and 222, whose influence on the electric characteristics or performance of the circuit element 220 is lower than a designated level may include the recess RC on an edge, in a plan view. FIG. 14 illustrates an example in which the first active region 221 includes the recess RC on an edge, and the second active region 222 does not include the recess RC on an edge. At this time, the first active region 221 may be an active region that has less influence on electric characteristics or performance of the circuit element 220 compared to the second active region 222.

However, implementations are not limited to the example shown in FIG. 14, and according to some implementations, the first active region 221 and the second active region 222 each may include the recess RC on an edge, in a plan view. In addition, the number and shape of the recess RC included in each active region may be changed in various ways.

According to some implementations, the area of the active region may be small. As the area of the active region is smaller, the junction capacitance of the circuit element 220 may decrease.

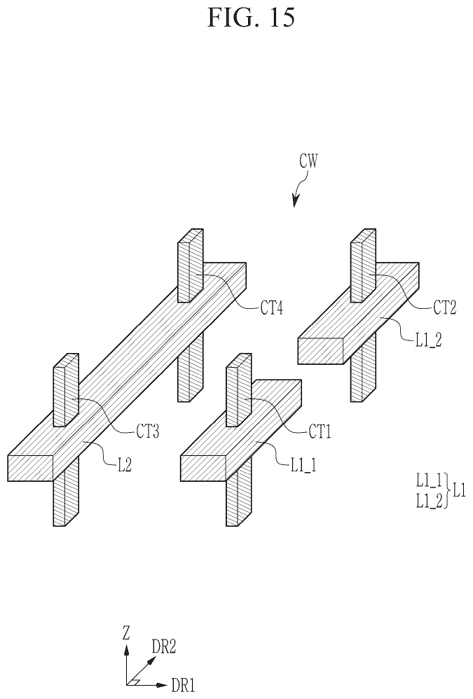

However, implementations are not limited to the examples shown in FIG. 13 and FIG. 14. According to some implementations, in a plan view, at least one active region among the plurality of active regions 221 and 222 of the circuit element 220 may have a quadrangular shape of which at least one corner portion is chamfered, and may include the recess RC on an edge. Hereinafter, referring to FIG. 15 to FIG. 18, various structures of the wires of each of the plurality of connection wire layers CW connected by the connection contact structure CC of the semiconductor device 10 will be described.

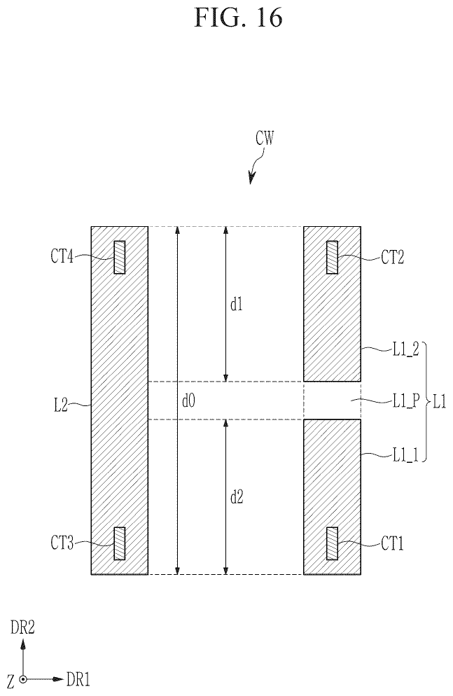

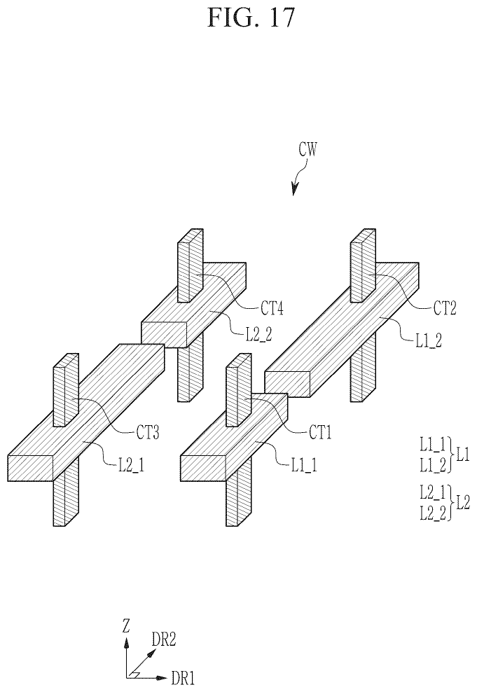

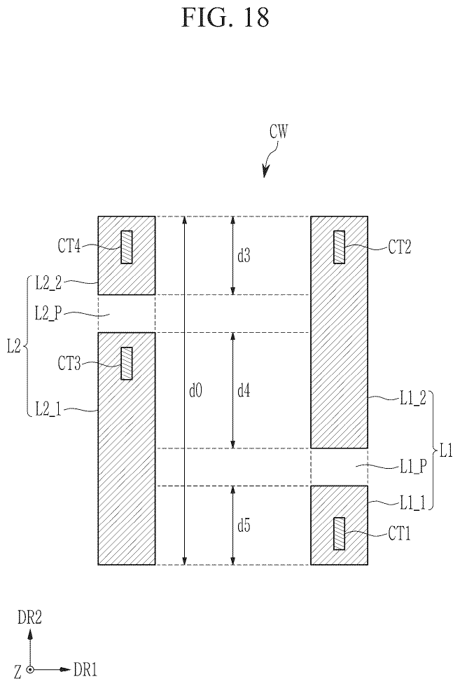

FIG. 15 and FIG. 17 are perspective views showing various wire structures of a connection wire layer connected by a connection contact structure of a semiconductor device according to some implementations. FIG. 16 and FIG. 18 are plan views showing various wire structures of a connection wire layer connected by a connection contact structure of a semiconductor device according to some implementations.

The connection wire layer CW shown in FIG. 15 to FIG. 18 may be the lower connection wire layer 250 (see FIG. 1) or upper insulation layer 132a and 132b (see FIG. 1). FIG. 15 to FIG. 18 illustrate only one connection wire layer CW for convenience, but the content to be described later may be applied to each of the plurality of connection wire layers CW spaced apart in a direction perpendicular to the upper surface of the substrate 210 (see FIG. 1) (Z direction). The wires included in the connection wire layers CW adjacent in the direction perpendicular to the upper surface of the substrate 210 (see FIG. 1) (Z direction) may extend in directions parallel to the upper surface of the substrate 210 (see FIG. 1) but perpendicular to each other. That is, wires of the plurality of connection wire layers CW may have a mesh shape, in a plan view.

Referring to FIG. 15 to FIG. 18, the connection wire layer CW includes a plurality of wires L1 and L2 arranged to be spaced apart from each other in a first direction DR1 parallel to the upper surface of the substrate 210 (see FIG. 1). Each of the plurality of wires L1 and L2 may extend in a second direction DR2 perpendicular to the first direction DR1. For example, the first direction DR1 may be the Y direction of FIG. 1, and the second direction DR2 may be the X direction of FIG. 1, but the first direction DR1 and the second direction DR2 are not necessarily limited thereto. The plurality of wires include a first wire L1 and a second wire L2 adjacent in the first direction DR1. Although FIG. 15 to FIG. 18 only illustrate adjacent two wires, it is not limited thereto, and the connection wire layer CW may include more wires.

For example, a first connection contact CT1 and a second connection contact CT2 may be connected to the first wire L1, and a third connection contact CT3 and a fourth connection contact CT4 may be connected to the second wire L2. The first wire L1 may be connected to another connection wire layer CW spaced apart from the connection wire layer CW shown in FIG. 15 and FIG. 16 in the direction perpendicular to the upper surface of the substrate 210 (see FIG. 1) (Z direction) by the first connection contact CT1 and the second connection contact CT2. The second wire L2 may be connected to another connection wire layer CW spaced apart from the connection wire layer CW shown in FIG. 15 to FIG. 18 in the direction perpendicular to the upper surface of the substrate 210 (see FIG. 1) (Z direction) by the third connection contact CT3 and the fourth connection contact CT4. The first wire L1 and the second wire L2 may be connected in another connection wire layer CW.

According to the implementations shown in FIG. 15 and FIG. 16, the first wire L1 includes a first portion L1_1 and a second portion L1_2 separated from each other. The first wire L1 includes a first separation portion L1_P between the first portion L1_1 and the second portion L1_2. The first separation portion L1_P may overlap with the second wire L2. In this case, area in which the first wire L1 and the second wire L2 face each other in the first direction DR1 may correspond to (d1+d2). According to some techniques in which the first wire L1 is separated but extends in parallel to the second wire L2, the area in which the first wire L1 and the second wire L2 face each other in the first direction DR1 may correspond to do. By comparison, according to some implementations, the area in which the first wire L1 and the second wire L2 face each other in the first direction DR1 may decrease.

According to the implementations shown in and FIG. 17 and FIG. 18, the first wire L1 includes the first portion L1_1 and the second portion L1_2 separated from each other, and the second wire L2 includes a third portion L2_1 and a fourth portion L2_2 separated from each other. The first wire L1 may include the first separation portion L1_P between the first portion L1_1 and the second portion L1_2. The second wire L2 may include a second separation portion L2_P between the third portion L2_1 and the fourth portion L2_2. The first separation portion L1_P between the first portion L1_1 and the second portion L1_2 may not overlap with the second separation portion L2_P between the third portion L2_1 and the fourth portion L2_2 in the first direction DR1. In this case, the area in which the first wire L1 and the second wire L2 face each other in the first direction DR1 may correspond to (d3+d4+d5).

According to some techniques in which the first wire L1 and the second wire L2 are not separated but extend in parallel to each other, the area in which the first wire L1 and the second wire L2 face each other in the first direction DR1 may correspond to do. By comparison, according to some implementations, the area in which the first wire L1 and the second wire L2 face each other in the first direction DR1 may decrease. In addition, according to the implementations shown in FIG. 17 and FIG. 18, the area in which the first wire L1 and the second wire L2 face each other in the first direction DR1 may further decrease compared to the implementations of FIG. 15 and FIG. 16.

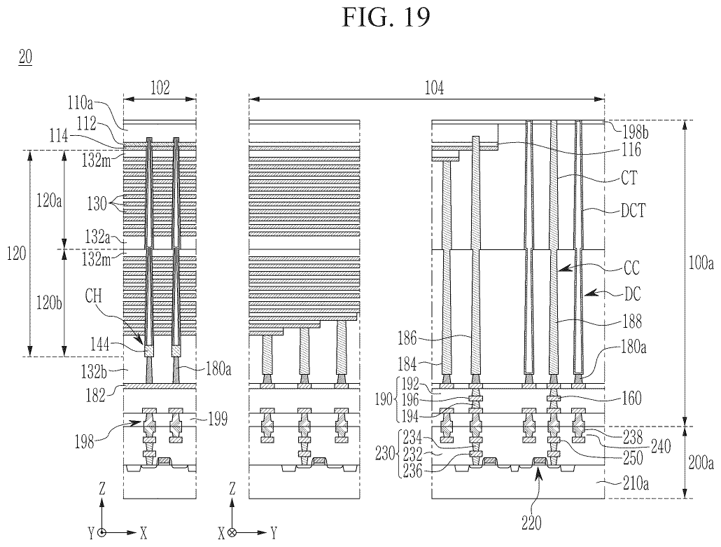

Hereinafter, referring to FIG. 19, a semiconductor device according to some implementations will be described.

FIG. 19 is a cross-sectional view showing a semiconductor device according to some implementations.

Since the implementations shown in FIG. 19 have many of the same parts as the implementations shown in FIG. 1 to FIG. 4, description thereof will be omitted and the differences will be mainly explained. In addition, the same reference numerals are used for the same components as those in the previous implementations.

Referring to FIG. 19, a semiconductor device 20 according to some implementations has a chip-to-chip (C2C) structure bonded using a wafer bonding method. That is, a lower chip including a circuit region 200a formed on a first substrate 210a may be manufactured, an upper chip including a cell region 100a formed on a second substrate 110a may be manufactured, and then the semiconductor device 20 may be manufactured by bonding them.

The circuit region 200a may be provided with the first substrate 210a, the circuit element 220, the first wiring portion 230, and a first bonding structure 238 electrically connected to the first wiring portion 230 and located on a surface facing the cell region 100a. In the surface facing the cell region 100a, regions other than a first bonding structure 240 may be covered by a first joint portion insulation layer 240.

The cell region 100a may be provided with the second substrate 110a, the gate stacked structure 120, the channel structure CH, the second wiring a second bonding structure 198 portion 190, and electrically connected to the second wiring portion 190 and located on a surface facing the circuit region 200a. Regions other than the second bonding structure 198 may be covered by a second joint portion insulation layer 199.

The second substrate 110a may be a semiconductor substrate including a semiconductor material. For example, the second substrate 110a may be a semiconductor substrate made of a semiconductor material, and may be a semiconductor substrate in which a semiconductor layer is formed on a base substrate. For example, the second substrate 110a may be formed of monocrystalline or polycrystalline silicon, germanium, silicon-germanium, silicon-on-insulator, germanium-on-insulator, or the like. Alternatively, the second substrate 110a may be configured as a support member including an insulation layer or an insulating material. This is because, after bonding the cell region 100a to the circuit region 200a, a semiconductor substrate provided in the cell region 100a may be removed and a support member including an insulation layer or an insulating material may be formed.

In some implementations, the gate stacked structure 120 may be sequentially stacked in a lower portion of the second substrate 110a in the drawing, and may be disposed in a structure in which the gate stacked structure 120 shown in FIG. 1 is inverted upside down. In addition, the channel structure CH penetrating the gate stacked structure 120 may also be disposed in a structure in which the gate stacked structure 120 shown in FIG. 1 is inverted upside down. Due to this, in cross-section, the channel structure CH may have an inclined side surface such that the width narrows from the circuit region 200a toward the second substrate 110a. In addition, the channel pad 144 and the second wiring portion 190 located on the gate stacked structure 120 may be located adjacent to the circuit region 200a.

For example, the first bonding structure 238 and/or the second bonding structure 198 may be formed of aluminum, copper, tungsten, or an alloy including the same. For example, first and second bonding structures 238 and 198 may include copper, such that the cell region 100a and the circuit region 200a may be bonded by copper-to-copper bonding (e.g., bonded in directly contact).

Except for those described separately, the description on the structure of the gate stacked structure 120 and the channel structure CH described above with reference to FIG. 1 to FIG. 4 may also be applied. FIG. 19 illustrates an example in which the electrical connection structure between the channel structure CH and the second substrate 110a is the same as in FIG. 2 and FIG. 3. Implementations are not limited thereto, and electrical connection structure between the channel structure CH and the second substrate 110 may be changed in various ways.

The semiconductor device 20 according to an example may include an input/output pad and an input/output connection wire electrically connected thereto. The input/output connection wire may be electrically connected to a portion of the second bonding structure 198. For example, the input/output pad may be located on an insulation layer 198b covering an exterior surface of the second substrate 110. Depending on the implementation, a separate input/output pad electrically connected to the circuit region 200a may be provided.

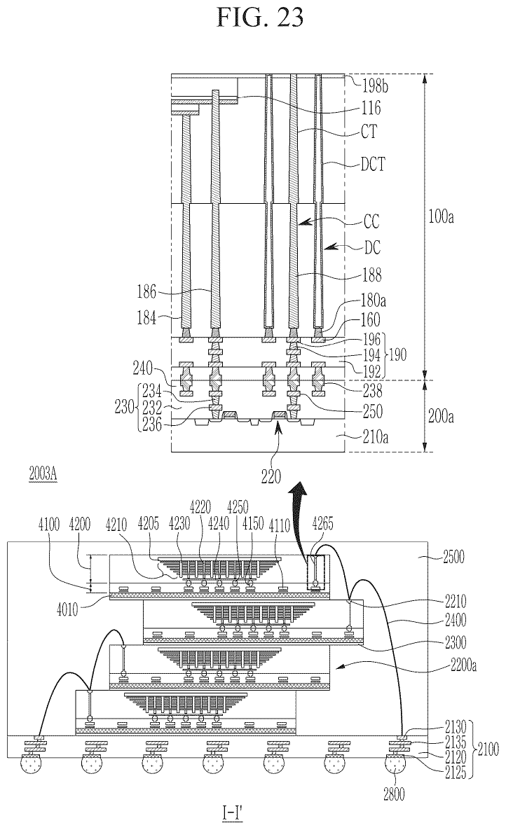

As an example, the circuit region 200a and the cell region 100a may be a portion corresponding to the first structure 1100F and the second structure 1100S of the semiconductor device 1100 included in the electronic system 1000 shown in FIG. 20, respectively. Alternatively, the circuit region 200a and the cell region 100a may be a portion corresponding to a first structure 4100 and a second structure 4200 of a semiconductor chip 2200a shown in FIG. 23, respectively.

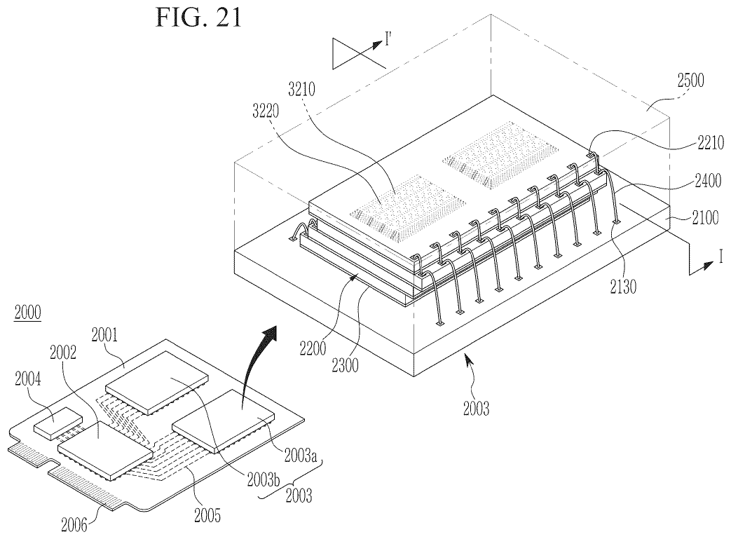

Hereinafter, referring to FIG. 20 and FIG. 21, an electronic system including a semiconductor device according to some implementations will be described.

FIG. 20 is a drawing schematically showing an electronic system including a semiconductor device according to some implementations.

Referring to FIG. 20, the electronic system 1000 according to some implementations includes the semiconductor device 1100 and a controller 1200 electrically connected to the semiconductor device 1100. The electronic system 1000 may be a storage device or an electronic device including the storage device, which includes one or a plurality of semiconductor devices 1100. For example, the electronic system 1000 may be a solid-state drive (SSD) device, a universal serial bus (USB), a computing system, a medical device or a communication apparatus, which includes one or the plurality of semiconductor devices 1100.

The semiconductor device 1100 may be a non-volatile memory device, and for example, may be a NAND flash memory device described above with reference to FIG. 1 to FIG. 4, or a NAND flash memory device described above with reference to FIG. 19. The semiconductor device 1100 includes the second structure 1100S on the first structure 1100F and the first structure 1100F. In some implementations, the first structure 1100F may be disposed side by side with the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a wordline WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR includes lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be changed in various ways depending on implementations.

In some implementations, the lower transistors LT1 and LT2 may include the ground select transistor, and the upper transistors UT1 and UT2 may include the string select transistor. The first and second gate lower lines LL1 and LL2 may be gate electrodes of the lower transistors LT1 and LT2, respectively. The wordline WL may be a gate electrode of the memory cell transistor MCT, and the gate upper lines UL1 and UL2 may gate electrodes of the upper transistors UT1 and UT2, respectively.

The common source line CSL, the first and second gate lower lines LL1 and LL2, the wordline WL, and the first and second gate upper lines UL1 and UL2 may be electrically connected to the decoder circuit 1110 through a first connection wire 1115 extending to the second structure 1100S within the first structure 1100F. The bit line BL may be electrically connected to the page buffer 1120 through a second connection wire 1125 extending to the second structure 1100S within the first structure 1100F.

In the first structure 1100F, the decoder circuit 1110 and the page buffer 1120 may execute control operations on at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending to the second structure 1100S within the first structure 1100F.

The controller 1200 includes a processor 1210, a NAND controller 1220, and a host interface 1230. Depending on the implementation, the electronic system 1000 may include the plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to a preset firmware, and access the semiconductor device 1100 by controlling the NAND controller 1220. The NAND controller 1220 includes a NAND interface 1221 configured to process communication with the semiconductor device 1100. Through the NAND interface 1221, a control command for controlling the semiconductor device 1100, data to write in the memory cell transistor MCT of the semiconductor device 1100, data to read from the memory cell transistor MCT of the semiconductor device 1100, or the like may be transmitted. The host interface 1230 may provide the communication function between the electronic system 1000 and an external host. When a control command is received from the external host through the host interface 1230, the processor 1210 may control the semiconductor device 1100 in response to the control command.

FIG. 21 is a perspective view schematically showing an electronic system including a semiconductor device according to some implementations.

Referring to FIG. 21, an electronic system 2000 according to some implementations includes a main substrate 2001, and a controller 2002, one or more a semiconductor package 2003, and a DRAM 2004 mounted on the main substrate 2001. The semiconductor package 2003 and the DRAM 2004 may be connected to the controller 2002 with each other by a wire pattern 2005 formed in the main substrate 2001.

The main substrate 2001 includes a connector 2006 including a plurality of pins coupled to the external host. In the connector 2006, the number and the arrangement of the plurality of pins may vary depending on the communication interface between the electronic system 2000 and the external host. In some implementations, the electronic system 2000 may communicate with the external host depending on one of interfaces such as a universal serial bus (USB), a peripheral component interconnect express (PCI-Express), a serial advanced technology attachment (SATA), M-Phy for a universal flash storage (UFS), or the like. In some implementations, the electronic system 2000 may operate by the power supplied from the external host through the connector 2006. The electronic system 2000 may further include a power management integrated circuit (PMIC) distributing the power supplied from the external host to the controller 2002 and the semiconductor package 2003.

The controller 2002 may record data in the semiconductor package 2003, or read data from the semiconductor package 2003, and may improve the operation speed of the electronic system 2000.

DRAM (2004) may be a buffer memory to alleviate the speed difference between the semiconductor package (2003), which is a data storage space, and the external host. The DRAM 2004 included in the electronic system 2000 may also operate as a kind of cache memory, and may provide a space for temporarily storing data during control operations for the semiconductor package 2003. When the DRAM 2004 is included in the electronic system 2000, the controller 2002 may further include a DRAM controller for controlling the DRAM 2004 in addition to a NAND controller for controlling the semiconductor package 2003.

The semiconductor package 2003 includes first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chip 2200 on the package substrate 2100, an adhesive layer 2300 disposed on a bottom surface of each of the semiconductor chip 2200, a connection structure 2400 electrically connecting the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each semiconductor chip 2200 includes an input/output pad 2210. The input/output pad 2210 may correspond to the input/output pad 1101 of FIG. 20. Each semiconductor chip 2200 includes a gate stacked structure 3210 and a channel structure 3220. The semiconductor chips 2200 may include the semiconductor device described above with reference to FIG. 1 to FIG. 4, or the semiconductor device described above with reference to FIG. 21, respectively.

In some implementations, the connection structure 2400 may be a bonding wire electrically connecting the input/output pad 2210 and the package upper pad 2130. Therefore, in each of the first and second semiconductor packages 2003a and 2003b, the semiconductor chip 2200 may be electrically connected to each other a bonding wire method, and may be electrically connected to the package upper pad 2130 of the package substrate 2100. Depending on the implementation, in each the first and second semiconductor packages 2003a and 2003b, the semiconductor chip 2200 may be electrically connected by a connection structure including a through-silicon via (TSV) to each other, instead of the connection structure 2400 of the bonding wire method.

In some implementations, the controller 2002 and the semiconductor chip 2200 may be included in one package. For example, the controller 2002 and the semiconductor chip 2200 may be mounted on a separate interposer board different from the main board 2001, and the controller 2002 and the semiconductor chip 2200 may be connected to each other by the wire formed on the interposer substrate.

FIG. 22 and FIG. 23 are cross-sectional views each schematically showing a semiconductor package according to some implementations. FIG. 22 and FIG. 23 may show implementations of the semiconductor package 2003 of FIG. 21, respectively, and may conceptually represent a cross-section region of the semiconductor package 2003 of FIG. 21 taken along line I-I′.

Referring to FIG. 22, in the semiconductor package 2003, the package substrate 2100 may be a printed circuit board. The package substrate 2100 includes a package substrate body portion 2120, the package upper pad 2130 disposed on an upper surface of the package substrate body portion 2120, a package lower pad 2125 disposed on a lower surface of the package substrate body portion 2120 or exposed through a lower surface, and an internal wire 2135 electrically connecting the package upper pad 2130 and the package lower pad 2125 within the package substrate body portion 2120. The package upper pad 2130 may be electrically connected to the connection structure 2400. The package lower pad 2125 may be connected to the wire pattern 2005 of the main substrate 2001 of the electronic system 2000 as shown in FIG. 21 through a conductive connection portion 2800.

The semiconductor chip 2200 includes the first structure 3100 and the second structure 3200 sequentially stacked on a semiconductor substrate 3010. The first structure 3100 may include a peripheral circuit region including a peripheral wire 3110. The second structure 3200 may include a common source line 3205, the gate stacked structure 3210 on the common source line 3205, the channel structure 3220 and a separation structure 3230 penetrating the gate stacked structure 3210, a bit line 3240 electrically connected to the channel structure 3220, and a gate connection wire electrically connected to wordline (see reference symbol WL of FIG. 20) of the gate stacked structure 3210.

The semiconductor chip 2200 or semiconductor device according to some implementations includes the dummy contact structure DC adjacent to the connection contact structure CC and having a lower dielectric constant than the connection contact structure CC, and thereby, in a direction parallel to the upper surface of the first substrate 210, parasitic capacitance of the connection contact structure CC may decrease.

Each semiconductor chip 2200 includes a penetration wire 3245 electrically connected to the peripheral wire 3110 of the first structure 3100 and extending into the second structure 3200. The penetration wire 3245 may penetrate the gate stacked structure 3210, and may be further disposed on an outer side of the gate stacked structure 3210. Each semiconductor chip 2200 may further include an input/output connection wire 3265 electrically connected to the peripheral wire 3110 of the first structure 3100 and extending into the second structure 3200 and the input/output pad 2210 electrically connected to the input/output connection wire 3265.

In some implementations, in the semiconductor package 2003, the plurality of semiconductor chips 2200 may be electrically connected to each other by the connection structure 2400 in the form of a bonding wire. As another example, the plurality of semiconductor chips 2200 or a plurality of portions constituting the same may be electrically connected by a connection structure including a through-silicon via (TSV).

Referring to FIG. 23, in a semiconductor package 2003A, each semiconductor chip 2200a includes a semiconductor substrate 4010, the first structure 4100 on the semiconductor substrate 4010, and the second structure 4200 bonded to the first structure 4100 in the wafer bonding method on the first structure 4100.

The first structure 4100 includes a peripheral wire 4110 and a peripheral circuit region including a first bonding structure 4150. The second structure 4200 includes a common source line 4205, a gate stacked structure 4210 between the common source line 4205 and the first structure 4100, channel structures 4220 and separation structures 4230 penetrating the gate stacked structure 4210, and second bonding structures 4250 electrically connected to wordlines (see reference symbol WL of FIG. 20, which is the same hereinbelow) of the channel structures 4220 and the gate stacked structure 4210, respectively. For example, the second bonding structures 4250 may be electrically connected to the channel structures 4220 and the wordlines WL, respectively, through a bit line 4240 electrically connected to the channel structure 4220 and a gate connection wire electrically connected to the wordline WL. The first bonding structure 4150 of the first structure 4100 and the second bonding structure 4250 of the second structure 4200 may be bonded in contact with each other. A bonded portion of the first bonding structure 4150 and the second bonding structure 4250 may be formed of, for example, copper (Cu).

The semiconductor chip 2200a or semiconductor device according to some implementations includes the dummy contact structure DC adjacent to the connection contact structure CC and having a lower dielectric constant than the connection contact structure CC, and thereby, in a direction parallel to the upper surface of the first substrate 210, parasitic capacitance of the connection contact structure CC may decrease.

Each semiconductor chip 2200a may further include the input/output pad 2210 and an input/output connection wire 4265 below the input/output pad 2210. The input/output connection wire 4265 may be electrically connected to a portion of the second bonding structure 4250.

In some implementations, in the semiconductor package 2003A, a plurality of semiconductor chips 2200a may be electrically connected to each other by the connection structure 2400 in the form of a bonding wire. As another example, the plurality of semiconductor chips 2200a or the plurality of portions constituting the same may be electrically connected by a connection structure including a through-silicon via.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination

While the present disclosure has been described in connection with what is presently considered to be practical implementations, it is to be understood that the disclosure is not limited to the disclosed implementations, but, on the contrary, is intended to cover various modifications and equivalent arrangements included within the spirit and scope of the appended claims.

What is claimed is:

1. A semiconductor device, comprising:
a substrate;
a circuit element and a wiring portion disposed on the substrate;
a gate stacked structure comprising a plurality of interlayer insulation layers and a plurality of gate electrodes alternately stacked on the wiring portion;
a channel structure extending through the gate stacked structure;
an upper insulation layer covering an upper surface of the wiring portion and the gate stacked structure;
a connection contact structure extending through the upper insulation layer at an outer side of the gate stacked structure and connected to the circuit element; and
a dummy contact structure disposed adjacent to the connection contact structure and having a lower dielectric constant than the connection contact structure.

2. The semiconductor device of claim 1, wherein the dummy contact structure is floating.

3. The semiconductor device of claim 2, wherein:
the connection contact structure comprises a connection contact connecting a plurality of connection wire layers, the plurality of connection wire layers being located in upper and lower portions of the upper insulation layer in a direction perpendicular to an upper surface of the substrate; and
the dummy contact structure comprises a dummy contact overlapping with the connection contact in a direction parallel to the upper surface of the substrate.

4. The semiconductor device of claim 3, wherein the dummy contact comprises:
a cover layer comprising a same material as the connection contact; and
an air gap located within the cover layer.

5. The semiconductor device of claim 3, wherein:
the dummy contact has a same cross-section shape as the connection contact;
the dummy contact comprises a material having a lower dielectric constant than the connection contact.

6. The semiconductor device of claim 3,
wherein the plurality of connection wire layers comprise a plurality of lower connection wire layers located in a lower portion of the upper insulation layer and a plurality of upper connection wire layers located in an upper portion of the upper insulation layer,
wherein the connection contact comprises:
a lower contact connecting at least one of: the plurality of lower connection wire layers, or the lower connection wire layer and the circuit element;
an upper contact connecting the plurality of upper connection wire layers; and
a through-contact connecting the lower connection wire layer and the upper connection wire layer by extending through the upper insulation layer, and
wherein the dummy contact overlaps with the through-contact in a direction parallel to the upper surface of the substrate.

7. The semiconductor device of claim 6, wherein the dummy contact further overlaps with at least one of the upper contact or the lower contact in a direction parallel to the upper surface of the substrate.

8. The semiconductor device of claim 3,
wherein the plurality of connection wire layers comprise a plurality of lower connection wire layers located in a lower portion of the upper insulation layer and a plurality of upper connection wire layers located in an upper portion of the upper insulation layer,
wherein the connection contact comprises:
a lower contact connecting (i) the plurality of lower connection wire layers with one another, or (ii) the plurality of lower connection wire layers with the circuit element;
an upper contact connecting the plurality of upper connection wire layers with one another; and
a through-contact extending through the upper insulation layer and connecting the lower connection wire layer and the upper connection wire layer, and
wherein the dummy contact overlaps with at least one of the upper contact or the lower contact in a direction parallel to the upper surface of the substrate.

9. The semiconductor device of claim 1, wherein:
the semiconductor device comprises a plurality of dummy contact structures; and
the plurality of dummy contact structures are disposed surrounding the connection contact structure.

10. The semiconductor device of claim 9, wherein a first one of the plurality of dummy contact structures is disposed on a first side of the connection contact structure, and a second one of the plurality of dummy contact structures is disposed on an opposite side of the connection contact structure.

11. The semiconductor device of claim 1, wherein the circuit element comprises:
a plurality of active regions located on an inner side from a surface of the substrate; and
a peripheral circuit gate electrode located between the plurality of active regions on the substrate,
wherein at least one active region among the plurality of active regions has a quadrangular shape, and wherein at least one corner portion of the quadrangular shape is chamfered.

12. The semiconductor device of claim 1, wherein the circuit element comprises:
a plurality of active regions located on an inner side from a surface of the substrate; and
a peripheral circuit gate electrode located between the plurality of active regions on the substrate,
wherein at least one active region among the plurality of active regions comprises a recess on an edge.

13. The semiconductor device of claim 1, further comprising a connection wire layer, wherein:
the connection wire layer comprises a plurality of wires spaced apart from each other in a first direction parallel to an upper surface of the substrate;
the plurality of wires comprises a first wire and a second wire adjacent to the first wire in the first direction; and
the first wire comprises a first portion and a second portion separated from each other.

14. The semiconductor device of claim 13, wherein:
the second wire comprises a third portion and a fourth portion separated from each other; and
a first separation portion between the first portion and the second portion does not overlap with a second separation portion between the third portion and the fourth portion in the first direction.

15. A semiconductor device, comprising:
a substrate;
a circuit element and a wiring portion disposed on the substrate;
a gate stacked structure comprising a plurality of interlayer insulation layers and a plurality of gate electrodes alternately stacked on the wiring portion;
a channel structure extending through the gate stacked structure;
an upper insulation layer covering an upper surface of the wiring portion and the gate stacked structure;
a connection contact structure extending through the upper insulation layer at an outer side of the gate stacked structure and being connected to the circuit element; and
a dummy contact structure disposed adjacent to the connection contact structure and comprising a different material from the connection contact structure.

16. The semiconductor device of claim 15, wherein:
the connection contact structure comprises a connection contact connecting a plurality of connection wire layers, the plurality of connection wire layers located in upper and lower portions of the upper insulation layer in a direction perpendicular to an upper surface of the substrate;
the dummy contact structure comprises a dummy contact overlapping with the connection contact in a direction parallel to the upper surface of the substrate; and
the dummy contact structure is floating.

17. The semiconductor device of claim 16, wherein the dummy contact comprises:
a cover layer comprising a same material as the connection contact, and
an air gap surrounded by the cover layer.

18. The semiconductor device of claim 16,
wherein the plurality of connection wire layers comprise a plurality of lower connection wire layers located in a lower portion of the upper insulation layer and a plurality of upper connection wire layers located in an upper portion of the upper insulation layer,
wherein the connection contact comprises:
a lower contact connecting (i) the plurality of lower connection wire layers with one another, or (ii) the plurality of lower connection wire layers with the circuit element;
an upper contact connecting the plurality of upper connection wire layers; and
a through-contact extending through the upper insulation layer and connecting the lower connection wire layer and the upper connection wire layer,
wherein the dummy contact overlaps with the through-contact in a direction parallel to the upper surface of the substrate.

19. The semiconductor device of claim 18, wherein the dummy contact further overlaps with at least one of the upper contact or the lower contact in a direction parallel to the upper surface of the substrate.

20. An electronic system, comprising:
a main substrate;
a semiconductor device on the main substrate; and
a controller electrically connected to the semiconductor device on the main substrate,
wherein the semiconductor device comprises
a semiconductor substrate;
a circuit element and a wiring portion disposed on the semiconductor substrate;
a gate stacked structure comprising a plurality of interlayer insulation layers and a plurality of gate electrodes alternately stacked on the wiring portion;
a channel structure extending through the gate stacked structure;
an upper insulation layer covering an upper surface of the wiring portion and the gate stacked structure;
a connection contact structure extending through the upper insulation layer at an outer side of the gate stacked structure and being connected to the circuit element; and
a dummy contact structure disposed adjacent to the connection contact structure and having a lower dielectric constant than the connection contact structure.
